(19) United States
(12) Patent Application Publication
(10) Pub. No.: US 2024/0130164 A1
(43) Pub. Date: Apr. 18, 2024

(54) DISPLAY DEVICE

(71) Applicant: SAMSUNG DISPLAY CO., LTD., YONGIN-SI (KR)

(72) Inventors: Byung Han YOO, YONGIN-SI (KR); Jung Woo PARK, YONGIN-SI (KR); Tae Kyung AHN, YONGIN-SI (KR); Gun Hee KIM, YONGIN-SI (KR); Dae Young LEE, YONGIN-SI (KR)

(21) Appl. No.: 18/353,681

(22) Filed: Jul. 17, 2023

(30) Foreign Application Priority Data
Oct. 18, 2022 (KR) 10-2022-0134200

(51) Int. Cl. H10K 59/122; H10K 39/34; H10K 59/35

(52) U.S. Cl. CPC H10K 59/122; H10K 39/34; H10K 59/353

(57) ABSTRACT

A display device includes a substrate and a plurality of unit pixels disposed on the substrate. Each unit pixel includes a plurality of sub-pixels, a plurality of light sensing pixels, and a plurality of partition wall members. Each of the sub-pixels includes a light emitting element that emits light and a light emitting area from which the light is emitted. Each of the light sensing pixels includes a light receiving element that outputs a sensing signal corresponding to the light and a light receiving area that receives the light. In a plan view, each of the partition wall members surrounds the corresponding light receiving area and overlaps at least some of the sub-pixels.

### CROSS-REFERENCE TO RELATED APPLICATIONS

This application claims priority under 35 U.S.C. § 119 to Korean Patent Application No. 10-2022-0134200, filed on Oct. 18, 2022, the disclosure of which is incorporated by reference herein in its entirety.

### TECHNICAL FIELD

Embodiments of the disclosure relate to a display device.

### DISCUSSION OF RELATED ART

As the use of display devices in electronic devices such as smartphones, tablet personal computers, etc. increases, the use of a biometric information authentication method using a user's fingerprint or the like has also increased. To provide a fingerprint sensing function, a fingerprint sensor may be provided in a form in which the fingerprint sensor is embedded in or attached to the display device.

A fingerprint sensor of a light sensing method may include a light source and a light sensor. The light sensor may obtain fingerprint information by receiving reflected light generated by the user's fingerprint.

### SUMMARY

Embodiments of the disclosure provide a display device capable of minimizing or reducing noise when a light sensing pixel senses light.

Embodiments of the disclosure provide a display device with increased accuracy in recognizing a pattern of a fingerprint of a user by a light sensing pixel.

According to embodiments of the disclosure, a display device includes a substrate, and a plurality of unit pixels disposed on the substrate. Each of the unit pixels includes a plurality of sub-pixels, a plurality of light sensing pixels, and a plurality of partition wall members. Each of the sub-pixels includes a light emitting element that emits light and a light emitting area from which the light is emitted. Each of the light sensing pixels includes a light receiving element that outputs a sensing signal corresponding to the light and a light receiving area that receives the light. In a plan view, each of the partition wall members surrounds the corresponding light receiving area and overlaps at least some of the sub-pixels.

In an embodiment, one of the unit pixels may include a first sub-pixel positioned in a first column of the substrate, two (2-1)-th sub-pixels positioned in a second column adjacent to the first column in a first direction, a third sub-pixel positioned in a third column adjacent to the second column in the first direction, two (2-2)-th sub-pixels positioned in a fourth column adjacent to the third column in the first direction, a first light sensing pixel positioned in the second column, and a second light sensing pixel positioned in the fourth column.

In an embodiment, the two (2-1)-th sub-pixels and the two (2-2)-th sub-pixels may emit light of the same color, and all of the color of the light emitted by the two (2-1)-th sub-pixels and the two (2-2)-th sub-pixels, a color of light emitted by the first sub-pixel, and a color of light emitted by the third sub-pixel may be different.

In an embodiment, the first light sensing pixel may be disposed between the two (2-1)-th sub-pixels in the second column, the second light sensing pixel may be disposed between the two (2-2)-th sub-pixels in the fourth column, and the first sub-pixel, the third sub-pixel, the first light sensing pixel, and the second light sensing pixel may be disposed in the same row.

In an embodiment, a partition wall member disposed in the second column among the partition wall members may be spaced apart from the first light sensing pixel and overlap the two (2-1)-th sub-pixels in at least a first partial area, and a partition wall member disposed in the fourth column among the partition wall members may be spaced apart from the second light sensing pixel and overlap the two (2-2)-th sub-pixels in at least a second partial area.

In an embodiment, in a plan view, each of the partition wall members may include an opening area in which at least a portion is opened.

In an embodiment, the opening area included in each of the partition wall members may correspond to a direction facing the first sub-pixel and the third sub-pixel.

In an embodiment, each of the partition wall members may include a first partition wall member and a second partition wall member having a quadrangular shape of which one side is opened, the first partition wall member and the second partition wall member included in the partition wall member disposed in the second column among the partition wall members may be spaced apart from each other with the first light sensing pixel interposed therebetween, and the first partition wall member and the second partition wall member included in the partition wall member disposed in the fourth column among the partition wall members may be spaced apart from each other with the second light sensing pixel interposed therebetween.

According to embodiments of the disclosure, a display device includes a substrate, a circuit layer disposed on the substrate and including a pixel circuit and a sensor circuit, a pixel element layer disposed on the circuit layer and including a light emitting element connected to the pixel circuit, a light receiving element connected to the sensor circuit, and a pixel defining layer disposed on the circuit layer, and a partition wall member disposed on the pixel defining layer. The partition wall member has a reverse taper shape, a first intermediate layer integrally formed with a light emitting layer of the light emitting element and a second intermediate layer integrally formed with a light receiving layer of the light receiving element may be disposed on the pixel defining layer, and the first intermediate layer and the second intermediate layer may be separated from each other with respect to the partition wall member on the pixel defining layer.

In an embodiment, an angle formed between a side surface and a lower surface of the partition wall member may exceed 90°.

In an embodiment, the light emitting element may include an anode electrode, the light emitting layer is positioned on the anode electrode, a cathode electrode is positioned on the light emitting layer, the light receiving element may include a first sensor electrode, the light receiving layer is positioned on the first sensor electrode, and a second sensor electrode is positioned on the light receiving layer.

In an embodiment, the cathode electrode and the second sensor electrode may include the same material.

In an embodiment, the cathode electrode and the second sensor electrode may be separated from each other with respect to the partition wall member.

In an embodiment, the pixel defining layer may be positioned on the anode electrode of the light emitting element and the first sensor electrode of the light receiving element, and may include a first opening exposing a portion of the anode electrode and a second opening exposing a portion the first sensor electrode.

In an embodiment, the light emitting layer may be disposed on the first opening and the light receiving layer may be disposed on the second opening, the first intermediate layer may be disposed on the pixel defining layer and may be integrally formed with the light emitting layer disposed on the first opening, and the second intermediate layer may be disposed on the pixel defining layer and may be integrally formed with the light receiving layer disposed on the second opening.

In an embodiment, the display device may further include a first dummy layer disposed on the partition wall member.

In an embodiment, the display device may further include a second dummy layer disposed on the first dummy layer.

In an embodiment, the cathode electrode, the second sensor electrode, and the second dummy layer may include the same material.

In an embodiment, the anode electrode and the first sensor electrode may include the same material.

In an embodiment, the display device may further include a thin film encapsulation layer positioned on the cathode electrode of the light emitting element and the second sensor electrode of the light receiving element and covering the light emitting element and the light receiving element.

### BRIEF DESCRIPTION OF THE DRAWINGS

The above and other features of the disclosure will become more apparent by describing in detail embodiments thereof with reference to the accompanying drawings, in which:

FIGS. 1 and 2 are plan views schematically illustrating a display device according to embodiments of the disclosure;

FIG. 3 is a schematic cross-sectional view of a display device according to embodiments of the disclosure;

FIG. 4 is a circuit diagram illustrating an example of a sub-pixel and a light sensing pixel included in the display device of FIG. 2 according to embodiments of the disclosure;

FIG. 5 is an enlarged cross-sectional view of a portion of a display panel included in the display device of FIG. 3 according to embodiments of the disclosure;

FIG. 6A is an enlarged view illustrating an example of a portion EA of the display device of FIG. 2 according to embodiments of the disclosure;

FIG. 6B is an enlarged view illustrating an example of the portion EA of the display device of FIG. 2 according to embodiments of the disclosure;

FIG. 7 is a cross-sectional view taken along a line I-I′ of FIG. 6A according to embodiments of the disclosure;

FIG. 8 is a cross-sectional view taken along a line II-IF of FIG. 6A according to embodiments of the disclosure;

FIG. 9 is a flowchart illustrating a method of manufacturing a display device according to embodiments of the disclosure; and

FIGS. 10A to 10E are cross-sectional views illustrating the method of manufacturing the display device of FIG. 9 according to embodiments of the disclosure.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings, and repeated descriptions of the same components may be omitted.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

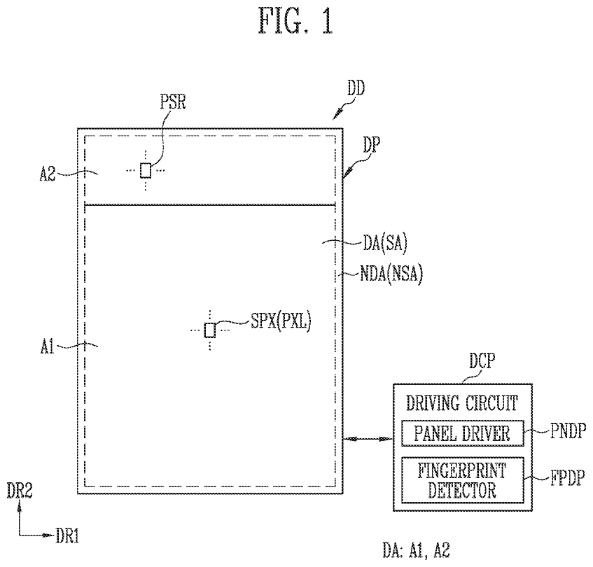

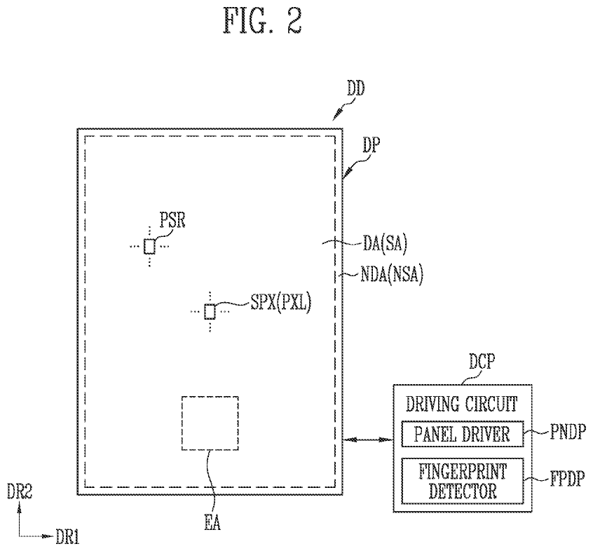

FIGS. 1 and 2 are plan views schematically illustrating a display device according to embodiments of the disclosure. FIGS. 1 and 2 show a display panel DP included in a display device DD according to embodiments of the disclosure and a driving circuit DCP that drives the display panel DP.

For convenience of description, although the display panel DP and the driving circuit DCP are shown separately in FIGS. 1 and 2, embodiments of the disclosure are not limited thereto. For example, according to an embodiment, all or a portion of the driving circuit DCP may be integrally implemented on the display panel DP.

Referring to FIGS. 1 and 2, the display device DD may include the display panel DP and the driving circuit DCP that drives the display panel DP.

The display device DD may be provided in various shapes. For example, the display device DD may be provided in a rectangular plate shape having two pairs of sides parallel to each other, but embodiments of the disclosure are not limited thereto. When the display device DD is provided in the rectangular plate shape, any one pair of sides of the two pairs of sides may be provided longer than the other pair of sides. For convenience of description,

FIGS. 1 and 2 show a case in which the display device DD has a rectangular shape having a pair of long sides and a pair of short sides, an extension direction of the pair of long sides is shown as a second direction DR2, and an extension direction of the pair of short sides is shown as a first direction DR1. According to an embodiment, the display device DD provided in the rectangular plate shape may have a round shape at a corner portion where one long side and one short side contact each other.

In an embodiment, at least a portion of the display device DD may have flexibility, and the display device DD may be folded at the portion having flexibility.

The display device DD may be, for example, a flat display device, a flexible display device, a curved display device, a foldable display device, or a bendable display device. In addition, the display device DD may be applied to, for example, a transparent display device, a head-mounted display device, a wearable display device, and the like.

The display panel DP may include a display area DA and a non-display area NDA. In the display area DA, sub-pixels SPX (or pixels PXL) may be provided, and thus, an image may be displayed in the display area DA. The non-display area NDA may be positioned on at least one side of the display area DA. For example, the non-display area NDA may be provided in a shape surrounding the display area DA.

A plurality of sub-pixels SPX may be provided in the display area DA. According to embodiments, each of the sub-pixels SPX may include at least one light emitting element. According to embodiments, the light emitting element may be, for example, a light emitting unit including an organic light emitting diode or an ultra-small inorganic light emitting diodes having a size of a micro to nano scale range, but embodiments of the disclosure are not limited thereto. The display device DD may display an image in the display area DA by driving the sub-pixels SPX in response to input image data.

The non-display area NDA may be an area surrounding at least one side of the display area DA, and may be a remaining area except for the display area DA. According to embodiments, the non-display area NDA may include, for example, a line area, a pad area, various dummy areas, and/or the like.

In an embodiment, one area of the display area DA may be set as a sensing area SA capable of sensing a user's fingerprint or the like. That is, at least a portion of the display area DA may be the sensing area SA. The sensing area SA may include at least some of the sub-pixels SPX provided in the display area DA.

In an embodiment, only a portion of the display area DA may be set as the sensing area SA. However, embodiments of the disclosure are not limited thereto. For example, in an embodiment, the entire display area DA may be set as the sensing area SA. When the entire display area DA is set as the sensing area SA, the non-display area NDA surrounding the display area DA may become a non-sensing area NSA. A plurality of light sensing pixels PSR (or light sensors) may be disposed in the sensing area SA together with the plurality of sub-pixels SPX.

Each of the light sensing pixels PSR may include a light receiving element including a light receiving layer. In the display area DA, the light receiving element may be spaced apart from the light emitting element.

According to embodiments, the plurality of light sensing pixels PSR may be distributed to be spaced apart from each other over the entire area of the display area DA. However, embodiments of the disclosure are not limited thereto. For example, as shown in FIG. 1, the display area DA may be divided into a first area A1 and a second area A2 in the second direction DR2, and the light sensing pixels PSR may be disposed only in the second area A2. In addition, as another example, the light sensing pixels PSR may be disposed in at least a portion of the non-display area NDA.

According to embodiments, the light sensing pixels PSR may sense that light emitted from a light source (for example, the light emitting element) is reflected by an external object (for example, a user's finger or the like). For example, the user's fingerprint may be sensed through each of the light sensing pixels PSR. Hereinafter, an embodiment in which the light sensing pixels PSR are used for a fingerprint sensing purpose is described as an example, but in various embodiments, the light sensing pixels PSR may sense various pieces of biometric information such as iris information and vein information. In addition, the light sensing pixels PSR may sense external light and may perform a function of, for example, a gesture sensor, a motion sensor, a proximity sensor, an illuminance sensor, an image sensor, and the like.

The driving circuit DCP may drive the display panel DP. For example, the driving circuit DCP may output a data signal corresponding to image data to the display panel DP, or may output a driving signal for the light sensing pixels PSR and receive an electrical signal (for example, a sensing signal) received from the light sensing pixels PSR. The driving circuit DCP may detect a user's fingerprint shape using the electrical signals.

According to embodiments, the driving circuit DCP may include a panel driver PNDP and a fingerprint detector FPDP (or a sensor driver). For convenience of description, although the panel driver PNDP and the fingerprint detector FPDP are shown as separate configurations in FIGS. 1 and 2, embodiments of the disclosure are not limited thereto. For example, at least a portion of the fingerprint detector FPDP may be integrated together with the panel driver PNDP or may operate in conjunction with the panel driver PNDP.

The panel driver PNDP may supply a data signal corresponding to an image data signal to the sub-pixels SPX of the display area DA while sequentially scanning the sub-pixels SPX. In this case, the display panel DP may display an image corresponding to the image data.

According to embodiments, the panel driver PNDP may supply a driving signal for fingerprint sensing to the sub-pixels SPX. Such a driving signal may be provided to the sub-pixels SPX so that the sub-pixels SPX emit light to operate as a light source for the light sensing pixels PSR. In addition, according to embodiments, the panel driver PNDP may supply the driving signal and/or another driving signal for the fingerprint sensing to the light sensing pixels PSR. However, embodiments of the disclosure are not limited thereto, and the driving signals for the fingerprint sensing may be provided by the fingerprint detector FPDP.

The fingerprint detector FPDP may detect biometric information such as a user's fingerprint based on the sensing signal received from the light sensing pixels PSR. According to embodiments, the fingerprint detector FPDP may supply the driving signals to the light sensing pixels PSR and/or the sub-pixels SPX.

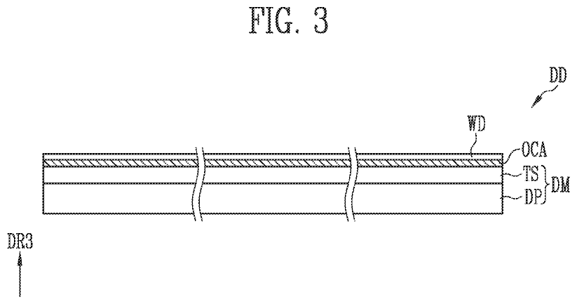

FIG. 3 is a schematic cross-sectional view of a display device according to embodiments of the disclosure. In FIG. 3, a thickness direction of the display device DD is shown as a third direction DR3.

Referring to FIG. 3, the display device DD may include a display module DM and a window WD.

The display module DM may include the display panel DP and a touch sensor TS.

The touch sensor TS may be directly disposed on the display panel DP or may be disposed on the display panel DP with a separate layer such as an adhesive layer or a substrate (or an insulating layer) interposed therebetween.

The display panel DP may display an image. In embodiments, a display panel capable of self-emission, such as an organic light emitting display panel (OLED panel), may be used as the display panel DP. However, embodiments of the disclosure are not limited thereto, and for example, a non-emission display panel such as a liquid crystal display panel (LCD panel), an electro-phoretic display panel (EPD panel), and an electro-wetting display panel (EWD panel) may be used as the display panel DP. When the non-emission display panel is used as the display panel DP, the display device DD may include a backlight unit that supplies light to the display panel DP.

The touch sensor TS may be disposed on a surface on which an image of the display panel DP is emitted to receive a touch input of a user. The touch sensor TS may recognize a touch event of the display device DD through a user's hand or a separate input means. The touch sensor TS may recognize the touch event in a capacitance method. For example, the touch sensor TS may sense the touch input in a mutual capacitance method or may sense the touch input in a self-capacitance method.

The window WD may protect an exposed surface of the display module DM, and may be disposed on the display module DM. The window WD may protect the display module DM from external impact, and may provide an input surface and/or a display surface to the user. The window WD may be coupled to the display module DM using an optically transparent adhesive member OCA.

The window WD may have a multiple layer structure selected from, for example, a glass substrate, a plastic film, and a plastic substrate. Such a multiple layer structure may be formed through a successive process or an adhesion process using an adhesive layer. The entire or a portion of the window WD may be flexible.

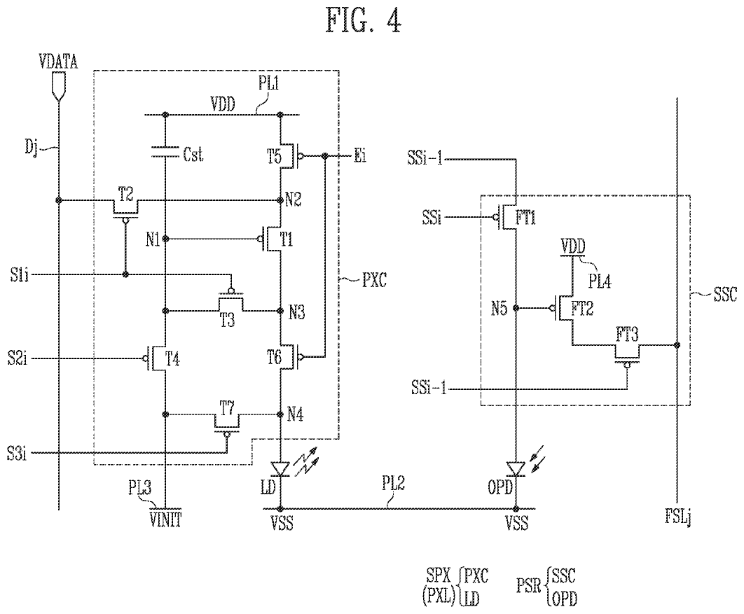

FIG. 4 is a circuit diagram illustrating an example of the sub-pixel and the light sensing pixel included in the display device of FIG. 2 according to embodiments of the disclosure.

In FIG. 4, for convenience of description, a sub-pixel SPX (or a pixel PXL) positioned on an i-th pixel row (or an i-th horizontal line) and connected to a j-th data line Dj, and a light sensing pixel PSR positioned on the i-th pixel row and connected to a j-th fingerprint sensing line FSLj (or a readout line FSLj) are shown (where, i and j are natural numbers).

Referring to FIGS. 1 to 4, the sub-pixel SPX may include a pixel circuit PXC and a light emitting element LD connected thereto, and the light sensing pixel PSR may include a sensor circuit SSC and a light receiving element OPD connected thereto.

One electrode (or an anode electrode) of the light emitting element LD may be connected to a fourth node N4, and another electrode (or a cathode electrode) may be connected to second driving power VSS. The light emitting element LD may generate light of a predetermined luminance in response to a current amount (driving current) supplied from the pixel circuit PXC.

According to embodiments, the light emitting element LD may be an organic light emitting diode including an organic light emitting layer. However, embodiments of the disclosure are not limited thereto, and the light emitting element LD may be an inorganic light emitting element formed of an inorganic material or a light emitting element formed of an inorganic material and an organic material in combination.

According to embodiments, the light receiving element OPD may be an organic photodiode. One electrode (or a first sensor electrode) of the light receiving element OPD may be connected to a fifth node N5, and another electrode (or a second sensor electrode) may be connected to the second driving power VSS. The light receiving element OPD may generate a carrier including a free electron and a hole based on an intensity of light incident to the light receiving layer, and may generate a current (photocurrent) by movement of the carrier.

The pixel circuit PXC may include a first transistor T1, a second transistor T2, a storage capacitor Cst, and the light emitting element LD. In addition, the pixel circuit PXC may further include third to seventh transistors T3, T4, T5, T6 and T7.

A gate electrode of the first transistor T1 (or a driving transistor T1) may be connected to a first node N1, a first electrode of the first transistor T1 may be connected to a second node N2, and a second electrode of the first transistor T1 may be connected to a third node N3.

The first transistor T1 may control a current amount flowing from first driving power VDD to the second driving power VSS via the light emitting element LD in response to a voltage of the first node N1. To this end, the first driving power VDD may be set to a voltage higher than that of the second driving power VSS.

The second transistor T2 (or a switching transistor T2) may be connected between the j-th data line Dj (hereinafter, referred to as a ‘data line Dj’) connected to the pixel PXL and the second node N2. A gate electrode of the second transistor T2 may be connected to an i-th first scan line S1i (hereinafter, referred to as a ‘first scan line S1i’) connected to the pixel PXL. The second transistor T2 may be turned on when a first scan signal is supplied to the first scan line S1i to electrically connect the data line Dj and the second node N2.

The third transistor T3 (or a compensation transistor T3) may be connected between the second electrode (that is, the third node N3) and the gate electrode (that is, the first node N1) of the first transistor T1. A gate electrode of the third transistor T3 may be connected to the first scan line S1i. The third transistor T3 may be turned on when the first scan signal is supplied to the first scan line S1i to electrically connect the second electrode (or the third node N3) and the gate electrode (or the first node N1) of the first transistor T1. That is, a timing at which the second electrode of the first transistor T1 and the gate electrode of the first transistor T1 are connected may be controlled by the first scan signal. When the third transistor T3 is turned on, the first transistor T1 may be connected in a diode form.

The fourth transistor T4 (or a first initialization transistor T4) may be connected between the first node N1 (or the gate electrode of the first transistor T1) and a third power line PL3 to which an initialization voltage VINIT is applied. A gate electrode of the fourth transistor T4 may be connected to an i-th second scan line S2i (hereinafter, referred to as a ‘second scan line S2i’). The fourth transistor T4 may be turned on in response to a second scan signal supplied to the second scan line S2i to supply the initialization voltage VINIT to the first node N1. Here, the initialization voltage VINIT may be set to a voltage lower than a data voltage VDATA supplied to the data line Dj. Accordingly, a gate voltage (or the voltage of the first node N1) of the first transistor T1 may be initialized to the initialization voltage VINT by the turn-on of the fourth transistor T4.

The fifth transistor T5 (or a first emission control transistor T5) may be connected between a first power line PL1 (or a first driving voltage line PL1) and the second node N2. A gate electrode of the fifth transistor T5 may be connected to an i-th emission control line Ei (hereinafter, referred to as an emission control line Ei). The fifth transistor T5 is turned on when an emission control signal is supplied to the emission control line Ei, and is turned off in other cases.

The sixth transistor T6 (or a second emission control transistor T6) may be connected between the second electrode (that is, the third node N3) of the first transistor T1 and the fourth node N4. A gate electrode of the sixth transistor T6 may be connected to the emission control line Ei. The sixth transistor T6 may be controlled substantially identically to the fifth transistor T5.

The fifth transistor T5 and the sixth transistor T6 may be turned on in response to the emission control signal supplied through the emission control line Ei, and may form a movement path of the driving current between the first power line PL1 and the fourth node N4 (or between the first power line PL1 and the second power line PL2).

In FIG. 4, the fifth transistor T5 and the sixth transistor T6 are connected to the same emission control line Ei, but this is an example, and the fifth transistor T5 and the sixth transistor T6 may be respectively connected to separate emission control lines to which different emission control signals are supplied according to embodiments.

The seventh transistor T7 (or a second initialization transistor T7) may be connected between the fourth node N4 and the third power line PL3. A gate electrode of the seventh transistor T7 may be connected to an i-th third scan line S3i (hereinafter, referred to as a ‘third scan line S3i’). The seventh transistor T7 may be turned on when a third scan signal is supplied to the third scan line S3i to supply the initialization voltage VINIT to the fourth node N4.

The storage capacitor Cst may be connected between the first power line PL1 and the first node N1. The storage capacitor Cst may store a difference voltage between a voltage of the first driving power VDD by the first power line PL1 and a voltage obtained by subtracting an absolute threshold voltage of the first transistor T1 from a data voltage applied to the first node N1.

In an embodiment, the first scan signal may be supplied after the second scan signal is supplied. For example, the second scan signal and the first scan signal may be supplied with a difference of one horizontal period.

In an embodiment, the third scan signal may be supplied simultaneously with the first scan signal. However, embodiments of the disclosure are not limited thereto, and the first scan signal may be supplied after the third scan signal is supplied. For example, a supply interval of the third scan signal and the first scan signal may be one horizontal period. Alternatively, the third scan signal may be supplied after the first scan signal is supplied.

The sensor circuit SSC may include a first sensor transistor FT1, a second sensor transistor FT2, and a third sensor transistor FT3.

The second sensor transistor FT2 and the third sensor transistor FT3 may be disposed between a sensing power line PL4 (or a fourth power line PL4) and a j-th fingerprint sensing line FSLj (hereinafter, referred to as a fingerprint sensing line FSLj) in series.

The first sensor transistor FT1 may be connected between an (i−1)-th sensing scan line SSi−1 (hereinafter, referred to as a previous sensing scan line SSi−1) and the fifth node N5 (or the first electrode of the light receiving element OPD). A gate electrode of the first sensor transistor FT1 may be connected to an i-th sensing scan line SSi (hereinafter, referred to as a sensing scan line SSi). The first sensor transistor FT1 may be turned on by a sensing scan signal supplied to the sensing scan line SSi to supply a voltage supplied to the previous sensing scan line SSi−1 to the fifth node N5. The first sensor transistor FT1 may be used to reset (or initialize) a voltage of the fifth node N5.

A gate electrode of the second sensor transistor FT2 may be connected to the fifth node N5. The second sensor transistor FT2 may generate a sensing current flowing from the sensing power line PL4 to the fingerprint sensing line FSLj based on the voltage of the fifth node N5 by the photocurrent generated by the light receiving element OPD.

In an embodiment, a gate electrode of the third sensor transistor FT3 may be connected to the previous sensing scan line SSi−1. The third sensor transistor FT3 may be turned on when a sensing scan signal is supplied to the previous sensing scan line SSi−1 to electrically connect the second sensor transistor FT2 and the fingerprint sensing line FSLj. Then, the sensing signal (sensing current) may be supplied to the fingerprint detector FPDP through the fingerprint sensing line FSLj.

According to embodiments, the first to seventh transistors T1 to T7 included in the pixel circuit PXC and the first to third sensor transistors FT1 to FT3 included in the sensor circuit SSC may be P-type transistors (for example, PMOS transistors), but embodiments of the disclosure are not limited thereto. For example, at least one of the first to seventh transistors T1 to T7 and the first to third sensor transistors FT1 to FT3 may be implemented as an N-type transistor (for example, an NMOS transistor). When the first to seventh transistors T1 to T7 and the first to third sensor transistors FT1 to FT3 are N-type transistors, positions of a source area (or a source electrode) and a drain area (or a drain electrode) may be reversely changed.

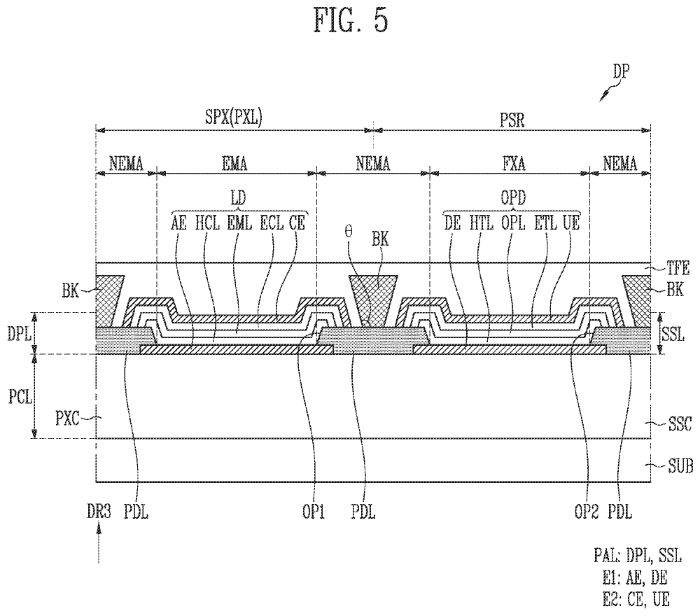

FIG. 5 is an enlarged cross-sectional view of a portion of the display panel included in the display device of FIG. 3 according to embodiments of the disclosure.

Referring to FIGS. 1 to 5, the display panel DP may include at least one sub-pixel SPX (or pixel PXL) and at least one light sensing pixel PSR.

The sub-pixel SPX may be disposed in a pixel area included in the display area DA. The pixel area may include a light emitting area EMA and a non-light emitting area NEMA adjacent to the light emitting area EMA. The light sensing pixel PSR may include a light receiving area FXA and the non-light emitting area NEMA adjacent to the light receiving area FXA.

The sub-pixel SPX may include the pixel circuit PXC (or a pixel circuit layer), a display element layer DPL, and a thin film encapsulation layer TFE sequentially positioned on a substrate SUB. The light sensing pixel PSR may include the substrate SUB, and the sensor circuit SSC (or a sensor circuit layer), a sensor layer SSL, and the thin film encapsulation layer TFE sequentially positioned on the substrate SUB.

The pixel circuit PXC included in the sub-pixel SPX and the sensor circuit SSC included in the light sensing pixel PSR may configure the circuit layer PCL, and the display element layer DPL included in the sub-pixel SPX and the sensor layer SSL included in the light sensing pixel PSR may configure a pixel element layer PAL.

The circuit layer PCL corresponding to the sub-pixel SPX may include the pixel circuit PXC disposed on the substrate SUB and signal lines connected to the pixel circuit PXC. In addition, the circuit layer PCL corresponding to the sub-pixel SPX may include at least one insulating layer positioned between configurations included in the pixel circuit PXC.

The display element layer DPL may be formed on the circuit layer PCL (or the pixel circuit PXC) of the sub-pixel SPX. The display element layer DPL may include the light emitting element LD that emits light. The light emitting element LD may include an anode electrode AE, a light emitting layer EML, and a cathode electrode CE.

The anode electrode AE may be electrically connected to the pixel circuit PXC.

The display element layer DPL of the sub-pixel SPX may include a pixel defining layer PDL including a first opening OP1 exposing a portion of the anode electrode AE. The pixel defining layer PDL may be disposed on the anode electrode AE and the circuit layer PCL.

A partition wall member BK may be formed on the pixel defining layer PDL.

In an embodiment, the partition wall member BK may have a reverse taper shape. For example, as shown in FIG. 5, a lower surface of the partition wall member BK may be in contact with at least a partial area of an upper surface of the pixel defining layer PDL, and the cross-sectional area of the partition wall member BK may increase as a distance from the pixel defining layer PDL increases along the third direction DR3. That is, the area of the upper surface of the partition wall member BK may be greater than the area of the lower surface of the partition wall member BK.

For example, in a cross-sectional view of the display panel DP shown in FIG. 5, an angle θ formed by a side surface (or an inclined surface) of the partition wall member BK and the lower surface may exceed 90° (for example, θ>90°).

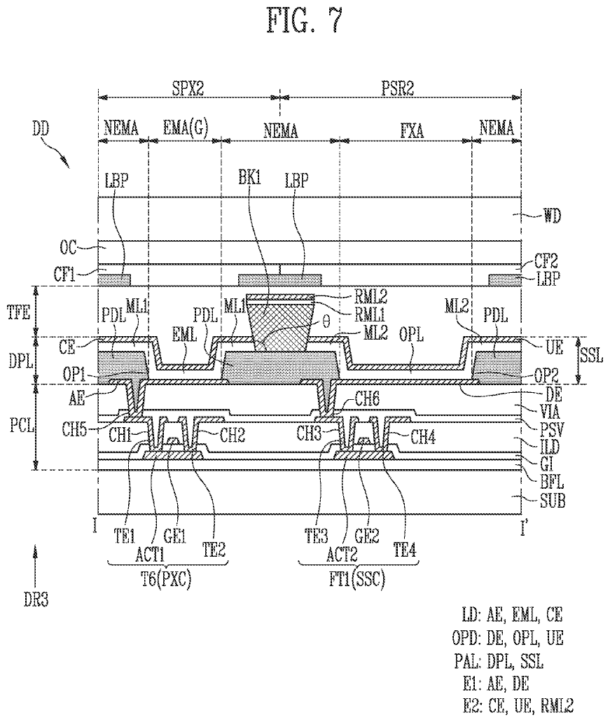

As described above, according to embodiments of the disclosure, since the partition wall member BK formed on the pixel defining layer PDL has the reverse taper shape, configurations (for example, layers) formed after the partition wall member BK is formed may be disposed separately by the partition wall member BK even though the configurations (for example, the layers) formed after the partition wall member BK is formed are formed using a common mask. That is, even though the configurations (for example, the layers) of the sub-pixel SPX and configurations (for example, layers) of the light sensing pixel PSR formed after the partition wall member BK is formed are formed using a common mask, the configurations (for example, the layers) of the sub-pixel SPX and the configurations (for example, the layers) of the light sensing pixel PSR formed after the partition wall member BK is formed may be disposed to be separated from each other by the partition wall member BK. Accordingly, when the light sensing pixels PSR sense light reflected by the external object (for example, the user's finger or the like), noise may be minimized or reduced. This is described in further detail with reference to FIGS. 7 to 10E.

In addition, the display element layer DPL may include a hole control layer HCL and an electron control layer ECL commonly provided to the light emitting area EMA and the non-light emitting area NEMA. The hole control layer HCL may include a hole transport layer, and may further include a hole injection layer. The hole control layer HCL may be disposed on the anode electrode AE and the pixel defining layer PDL exposed by a first opening OP1 of the pixel defining layer PDL. The light emitting layer EML may be disposed on the hole control layer HCL of the light emitting area EMA. An electron control layer ECL may be disposed on the light emitting layer EML. The electron control layer ECL may include an electron transport layer, and may further include an electron injection layer. The cathode electrode CE may be disposed on the electronic control layer ECL.

The circuit layer PCL corresponding to the light sensing pixel PSR may include the sensor circuit SSC disposed on the substrate SUB and signal lines connected to the sensor circuit SSC. In addition, the circuit layer PCL corresponding to the light sensing pixel PSR may include at least one insulating layer positioned between configurations included in the sensor circuit SSC.

The sensor layer SSL may be formed on the circuit layer PCL (or the sensor circuit SSC) of the light sensing pixel PSR. The sensor layer SSL may include the light receiving element OPD that receives light. The light receiving element OPD may include a first sensor electrode DE, a light receiving layer OPL, and a second sensor electrode UE.

The first sensor electrode DE may be electrically connected to the sensor circuit SSC. The first sensor electrode DE of the light sensing pixel PSR and the anode electrode AE of the sub-pixel SPX may configure a first electrode layer E1. For example, the first sensor electrode DE and the anode electrode AE may be simultaneously formed of the same material by the same process, but are not limited thereto.

The sensor layer SSL of the light sensing pixel PSR may include a pixel defining layer PDL including a second opening OP2 exposing a portion of the first sensor electrode DE. The pixel defining layer PDL may be the pixel defining layer PDL of the sub-pixel SPX. The pixel defining layer PDL may be disposed on the first electrode layer E1 and the circuit layer PCL.

In addition, as described above, the partition wall member BK may be formed on the pixel defining layer PDL.

In addition, the sensor layer SSL may include a hole transport layer HTL and an electron transport layer ETL commonly provided to the light receiving area FXA and the non-light emitting area NEMA. The hole transport layer HTL may be formed of the same material by the same process as the hole control layer HCL of the sub-pixel SPX. In an embodiment, the hole control layer HCL of the sub-pixel SPX and the hole transport layer HTL of the light sensing pixel PSR formed by the same process may be formed (or disposed) to be separate from each other, by the partition wall member BK having the reverse taper shape.

The hole transport layer HTL may be disposed between the first sensor electrode DE and the light receiving layer OPL. The light receiving layer OPL may be disposed on the hole transport layer HTL of the light receiving area FXA. The electron transport layer ETL may be formed of the same material by the same process as the electron control layer ECL of the sub-pixel SPX. In an embodiment, the electron control layer ECL of the sub-pixel SPX and the electron transport layer ETL of the light sensing pixel PSR formed by the same process may be formed (or disposed) to be separate from each other, by the partition wall member BK having the reverse taper shape.

In an embodiment, in a process of forming the light emitting layer EML of the sub-pixel SPX and a process of forming the light receiving layer OPL of the light sensing pixel PSR, the light emitting layer EML of the sub-pixel SPX and the light receiving layer OPL of the light sensing pixel PSR may not be connected (or contacted) and may be formed (or disposed) to be separated from each other, by the partition wall member BK having the reverse taper shape.

The second sensor electrode UE may be disposed on the electron control layer ECL. The second sensor electrode UE of the light sensing pixel PSR and the cathode electrode CE of the sub-pixel SPX may configure a second electrode layer E2.

According to embodiments, the cathode electrode CE of the sub-pixel SPX and the second sensor electrode UE of the light sensing pixel PSR may be formed of the same material by the same process. In addition, the cathode electrode CE and the second sensor electrode UE may be electrically connected to the second power line PL2 that transfers a voltage of the second driving power VSS, as shown in FIG. 4.

In an embodiment, the cathode electrode CE of the sub-pixel SPX and the second sensor electrode UE of the light sensing pixel PSR formed by the same process may be formed (or disposed) to be separate from each other, by the partition wall member BK having the reverse taper shape.

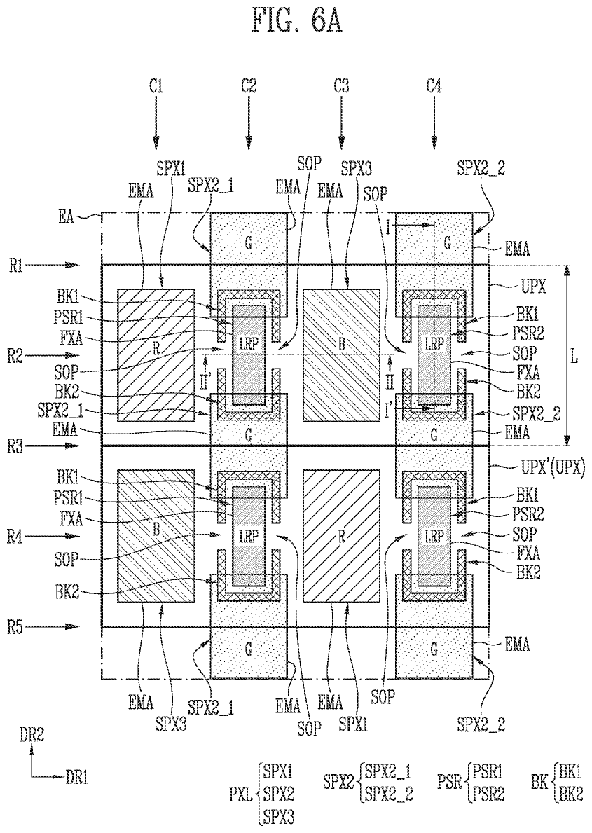

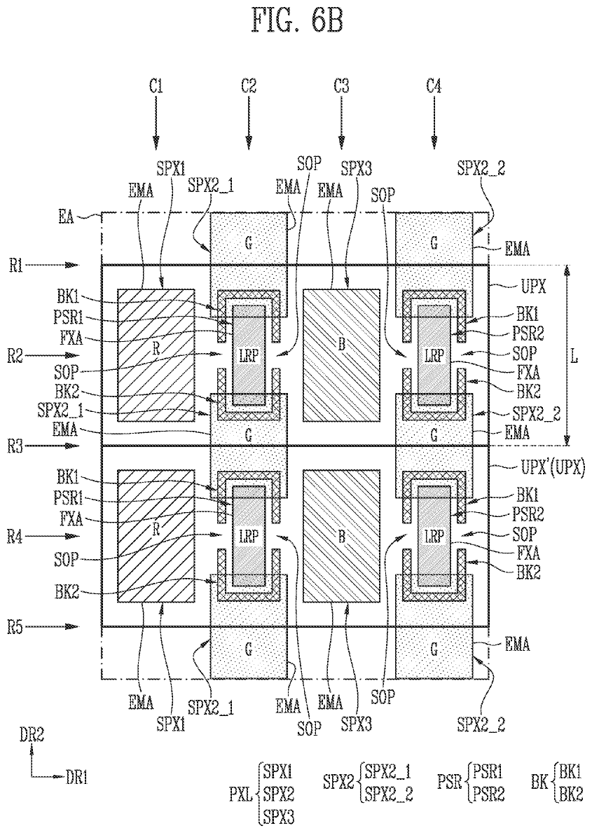

However, when the cathode electrode CE and the second sensor electrode UE are completely separated, the second sensor electrode UE (or the cathode electrode CE) may be disconnected from the second power line PL2, and thus the second sensor electrode UE (or the cathode electrode CE) may not receive the voltage of the second driving power VSS. Therefore, the cathode electrode CE and the second sensor electrode UE are formed in an interconnected form in a partial area. Accordingly, according to embodiments of the present disclosure, the partition wall member BK may include an opening area at least partially opened on a plane (for example, a plane defined by a first direction axis along the first direction DR1 and a second direction axis along the second direction DR2). This is further described with reference to FIGS. 6A and 6B.

The thin film encapsulation layer TFE may be provided and/or formed on the display element layer DPL of the sub-pixel SPX and the sensor layer SSL of the light sensing pixel PSR.

The thin film encapsulation layer TFE may be formed as a single layer, but may also be formed as multiple layers. The thin film encapsulation layer TFE may include a plurality of insulating layers covering the light emitting element LD and the light receiving element OPD. For example, the thin film encapsulation layer TFE may include at least one inorganic layer and at least one organic layer. For example, the thin film encapsulation layer TFE may have a structure in which an inorganic layer and an organic layer are alternately stacked. According to embodiments, the thin film encapsulation layer TFE may be an encapsulation substrate disposed on the light emitting element LD and the light receiving element OPD and bonded to the substrate SUB through a sealant.

FIG. 6A is an enlarged view illustrating an example of a portion EA of the display device of FIG. 2 according to embodiments of the disclosure. FIG. 6B is an enlarged view illustrating an example of the portion EA of the display device of FIG. 2 according to embodiments of the disclosure.

For convenience of description, in FIGS. 6A and 6B, a width direction (or a horizontal direction) on the plane is shown as the first direction DR1, and a height direction (or a vertical direction) on the plane is shown as the second direction DR2.

Referring to FIGS. 2, 5, and 6A, sub-pixels SPX1, SPX2, and SPX3 (or the pixels PXL) and the light sensing pixels PSR may be disposed in the display area DA (or the sensing area SA) of the display device DD.

Hereinafter, for convenience of description, the first sub-pixel SPX1, the second sub-pixel SPX2, and the third sub-pixel SPX3 may indicate the light emitting area EMA of each sub-pixel, and the light emitting area EMA may be defined by the first opening (for example, the first opening OP1 of FIG. 5) of the pixel defining layer (for example, the pixel defining layer PDL of FIG. 5). In addition, the light sensing pixel PSR may indicate the light receiving area FXA of the light sensing pixel PSR, and the light receiving area may be defined by the second opening (for example, the second opening OP2 of FIG. 5) of the pixel defining layer (for example, the pixel defining layer PDL of FIG. 5).

The sub-pixels SPX1, SPX2, and SPX3 (or the pixels PXL) disposed in the display area DA may be spaced apart from each other. The first sub-pixel SPX1 (or a first pixel), the second sub-pixel SPX2 (or a second pixel), and the third sub-pixel SPX3 (or a third pixel) may emit (or implement) light of different colors, respectively. For example, the first sub-pixel SPX1 may emit a first color light (for example, red light R), the second sub-pixel SPX2 may emit a second color light (for example, green light G), and the third sub-pixel SPX3 may emit a third color light (for example, blue light B). However, this is an example, and emission colors of the sub-pixels SPX1, SPX2, and SPX3 are not limited thereto.

The second sub-pixels SPX2 may be divided into a (2-1)-th sub-pixel SPX2_1 and a (2-2)-th sub-pixel SPX2_2. For example, the (2-1)-th sub-pixel SPX2_1 and the (2-2)-th sub-pixel SPX2_2 may be alternately disposed along the first direction DR1 in the same pixel row (or the same horizontal line).

The second sub-pixels SPX2 may be disposed in a first row R1. The first sub-pixel SPX1 and the third sub-pixel SPX3 may be alternately disposed in a second row R2 adjacent to the first row R1 in the second direction DR2. In addition, the light sensing pixel PSR may be disposed between the first sub-pixel SPX1 and the third sub-pixel SPX3 in the second row R2. The second sub-pixels SPX2 may be disposed in a third row R3 adjacent to the second row R2 in the second direction DR2. The third sub-pixel SPX3 and the first sub-pixel SPX1 may be alternately disposed in a fourth row R4 adjacent to the third row R3 in the second direction DR2. In addition, the light sensing pixel PSR may be disposed between the third sub-pixel SPX3 and the first sub-pixel SPX1 in the fourth row R4. The second sub-pixels SPX2 may be disposed in a fifth row R5 adjacent to the fourth row R4 in the second direction DR2.

The second sub-pixels SPX2 disposed in the first row R1 may be disposed to cross the first sub-pixel SPX1 and the third sub-pixel SPX3 disposed in the second row R2. The second sub-pixels SPX2 disposed in the third row R3 may be disposed to cross the first sub-pixel SPX1 and the third sub-pixel SPX3 disposed in the second row R2. In addition, the second sub-pixels SPX2 disposed in the third row R3 may be disposed to cross the third sub-pixel SPX3 and the first sub-pixel SPX1 disposed in the fourth row R4. The second sub-pixels SPX2 disposed in the fifth row R5 may be disposed to cross the third sub-pixel SPX3 and the first sub-pixel SPX1 disposed in the fourth row R4.

The first sub-pixel SPX1 disposed in the second row R2 and the third sub-pixel SPX3 disposed in the fourth row R4 may be disposed in the same column (for example, a first column C1).

The second sub-pixel SPX2 of the first row R1, the light sensing pixel PSR of the second row R2, the second sub-pixel SPX2 of the third row R3, the light sensing pixel PSR of the fourth row R4, and the second sub-pixel SPX of the fifth row R5 may be disposed in a second column C2 adjacent to the first column C1 in the first direction DR1.

The third sub-pixel SPX3 of the second row R2 and the first sub-pixel SPX1 of the fourth row R4 may be disposed in a third column C3 adjacent to the second column C2 in the first direction DR1.

The second sub-pixel SPX2 of the first row R1, the light sensing pixel PSR of the second row R2, the second sub-pixel SPX2 of the third row R3, the light sensing pixel PSR of the fourth row R4, and the second sub-pixel SPX2 of the fifth row R5 may be disposed in a fourth column C4 adjacent to the third column C3 in the first direction DR1.

In FIG. 6A, the first sub-pixel SPX1 and the third sub-pixel SPX3 are alternately arranged in the first column C1, and the third sub-pixel SPX3 and the first sub-pixel SPX1 are alternately disposed in the third column C3, but this is an example, and embodiments of the disclosure are not limited thereto.

For example, referring further to FIG. 6B, the first sub-pixels SPX1 may be disposed in the first column C1, and the third sub-pixels SPX3 may be disposed in the third column C3. For example, the first sub-pixel SPX1 of the second row R2 and the first sub-pixel SPX1 of the fourth row R4 may be disposed in the first column C1, and the third sub-pixel SPX3 of the second row R2 and the third sub-pixel SPX3 of the fourth row R4 may be disposed in the third column C3.

Referring to FIG. 6A again, hereinafter, for convenience of description, the second sub-pixels SPX2 positioned in the second column C2 are referred to as the (2-1)-th sub-pixels SPX2_1, and the second sub-pixels SPX2 positioned in the fourth column C4 are referred to as the (2-2)-th sub-pixels SPX2_2.

A plurality of repeatedly arranged unit pixels UPX may be disposed in the display area DA.

Each of the unit pixels UPX may include a plurality of predetermined sub-pixels SPX1, SPX2, and SPX3 and a plurality of predetermined light sensing pixels PSR. For example, one unit pixel UPX may include the first and third sub-pixels SPX1 and SPX3 positioned in the same row (for example, the second row R2) and adjacent in the first direction DR1, two light sensing pixels PSR positioned in the same row (for example, the second row R2) as the first and third sub-pixels SPX1 and SPX3 and spaced apart from the first and third sub-pixels SPX1 and SPX3 in different columns (for example, the second column C2 and the fourth column C4) (hereinafter, the light sensing pixel PSR positioned in the second column C2 is referred to as a first light sensing pixel PSR1, and the light sensing pixel PSR positioned in the column C4 is referred to as a second light sensing pixel PSR2), two (2-1)-th sub-pixels SPX2_1 positioned in a row adjacent to the first light sensing pixel PSR1 (for example, the first row R1 and the third row R3) and in the same column (for example, the second column C2), and two (2-2)-th sub-pixels SPX2_2 positioned in a row adjacent to the second light sensing pixel PSR2 (for example, the first row R1 and the third row R3) and in the same column (for example, the fourth column C4).

One unit pixel UPX and an adjacent unit pixel UPX′ adjacent to one unit pixel UPX in the second direction DR2 may share one (2-1)-th sub-pixel SPX2_1 and one (2-2)-th sub-pixel SPX2_2.

Each of one first sub-pixel SPX1, a plurality of second sub-pixels SPX2, and one third sub-pixel SPX3 included in one unit pixel UPX may include the light emitting area EMA. Each of the first light sensing pixel PSR1 and the second light sensing pixel PSR2 included in a corresponding unit pixel UPX may include the light receiving area FXA. The light receiving area FXA may correspond to the light receiving element OPD, for example, a light receiving portion LRP.

In an embodiment, configurations positioned within one unit pixel UPX may be spaced apart from each other by a constant distance.

For example, each of the sub-pixels SPX1, SPX2, and SPX3 may be spaced apart from each other in one unit pixel UPX. Distances at which the sub-pixels SPX1, SPX2, and SPX3 are spaced apart from each other within the corresponding unit pixel UPX may be different. For example, the distances at which the sub-pixels SPX1, SPX2, and SPX3 are spaced apart from each other in the corresponding unit pixel UPX may be designed to be equal to or greater than a CD width utilized for the display device DD. The above-described CD width may mean a distance (e.g., a smallest distance) between the sub-pixels SPX1, SPX2, and SPX3 within a range in which light emitted from each sub-pixel and light emitted from a sub-pixel adjacent to a corresponding sub-pixel do not affect each other. This is an example, and the disclosure is not limited thereto. For example, the distances at which the sub-pixels SPX1, SPX2, and SPX3 are spaced apart from each other in the corresponding unit pixel UPX may be determined according to resolution of the display device DD according to embodiments.

According to embodiments, each of the sub-pixels SPX1, SPX2, and SPX3 included in each unit pixel UPX may have a polygonal planar shape of light emitting area EMA defined (or partitioned) by the pixel defining layer PDL. For example, each of the sub-pixels SPX1, SPX2, and SPX3 may have a quadrangular planar shape of light emitting area EMA. For example, each of the sub-pixels SPX1, SPX2, and SPX3 may have a rectangular planar shape of light emitting area EMA including a pair of long sides parallel to the second direction DR2 and a pair of short sides parallel to the first direction DR1. However, this is an example, and a planar shape of the light emitting area EMA included in each of the sub-pixels SPX1, SPX2, and SPX3 may be variously set according to embodiments.

According to embodiments, each of the light sensing pixels PSR included in each unit pixel UPX may have a polygonal planar shape of light receiving area FXA defined (or partitioned) by the pixel defining layer PDL. For example, each of the light sensing pixels PSR may have a quadrangular planar shape of light receiving area FXA. For example, each of the light sensing pixels PSR may have a rectangular planar shape of light receiving area FXA including a pair of long sides parallel to the second direction DR2 and a pair of short sides parallel to the first direction DR1. However, this is an example, and a planar shape of the light receiving area FXA included in each of the light sensing pixels PSR may be variously set according to embodiments.

In an embodiment, the planar shape of the light receiving area FXA included in each of the light sensing pixels PSR and the planar shape of the light emitting area EMA included in each of the sub-pixels SPX1, SPX2, and SPX3 may be different from each other. For example, a ratio of the long side to the short side of the light receiving area FXA included in each of the light sensing pixels PSR and a ratio of the long side to the short side of the light emitting area EMA included in each of the sub-pixels SPX1, SPX2, and SPX3 may be different from each other. However, this is an example, and embodiments of the disclosure are not limited thereto. For example, the planar shape of the light receiving area FXA included in each of the light sensing pixels PSR and the planar shape of the light emitting area EMA included in each of the sub-pixels SPX1, SPX2, and SPX3 may be substantially the same.

However, this is an example, and positions, areas, shapes, and/or the like of the light emitting areas EMA and the light receiving areas FXA are not limited thereto.

The light emitting area EMA of the first sub-pixel SPX1 may be an area in which the red light R is emitted, the light emitting area EMA of each of the second sub-pixels SPX2 may be an area in which the green light G is emitted, and the light emitting area EMA of the third sub-pixel SPX3 may be an area in which the blue light B is emitted. The light receiving area FXA of each of the light sensing pixels PSR may be an area that receives the light R, G, and B emitted from at least some of the first to third sub-pixels SPX1, SPX2, and SPX3.

In an embodiment, the light sensing pixels PSR may sense light of a wavelength of bands identical or similar to each other or light of a wavelength of bands different from each other. For example, the light receiving area FXA of each of the light sensing pixels PSR may sense light of a wavelength band corresponding to one of the red light R, the green light G, and the blue light B. For example, the light receiving area FXA of each of the light sensing pixels PSR may be an area that receives the second color light (for example, the green light G) emitted from the second sub-pixels SPX2. However, this is merely an example, and embodiments of the disclosure are not limited thereto.

In an embodiment, the area of each of the light receiving areas FXA may be less than the area of each of the light emitting areas EMA. Therefore, image quality degradation due to insertion of the light receiving area FXA may be minimized or reduced.

As described, according to an embodiment, a length L of one unit pixel UPX in the second direction DR2 may be determined according to the resolution of the display device DD. When the length L of one unit pixel UPX is determined, the area of the second sub-pixel SPX2 finally emitting the green light G (for example, the area of the light emitting area EMA of the second sub-pixel SPX2) may be determined according to a ratio of each of the red light R, the green light G, and the blue light B determined in advance within a corresponding unit pixel UPX. That is, when the area (or a size) of the light emitting area EMA of the second sub-pixel SPX2 is determined, the area (or a size) of the light emitting area EMA of each of the first and third sub-pixels SPX1 and SPX3 may be determined. For example, in the corresponding unit pixel UPX, the area of each of the first to third sub-pixels SPX1, SPX2, and SPX3 may be determined so that each of the first to third sub-pixels SPX1, SPX2, and SPX3 has the light emitting area EMA having a polygonal (for example, quadrangular) of planar shape. As a result, at least one light sensing pixel PSR including the light receiving element OPD may be disposed in the corresponding unit pixel UPX.

In general, in a case of a display device including a light sensor attached to a rear surface of a substrate, since a proceed path of light emitted from the light emitting element, reflected by the user's finger, and incident on the light sensor is long, sensing capability of the light sensor may be reduced, and as the light sensor is attached to the rear surface of the substrate, the entire thickness of the display device may be increased.

According to embodiments, to prevent or reduce loss of light proceeding to the light sensor while implementing a slimmer display device, the light sensing pixels PSR including the light receiving element OPD adjacent to the sub-pixels SPX1, SPX2, and SPX3 in one unit pixel UPX may be disposed. Accordingly, sensing capability (sensing accuracy, or recognition rate) of the light sensing pixel PSR may be increased by increasing an amount of light input (or incident) to the light sensing pixel PSR.

As the resolution of the display device DD increases, a distance between configurations positioned in one unit pixel UPX may be decreased, and as described above, when the light sensing pixels PSR are disposed adjacent to the sub-pixels SPX1, SPX2, and SPX3 in one unit pixel UPX, a case where a portion of the sub-pixels SPX1, SPX2, and SPX3 (for example, the light emitting layer of the sub-pixels SPX1, SPX2, and SPX3) overlaps a portion of the light sensing pixels PSR (for example, the light receiving layer of the light sensing pixels PSR) according to a process error or the like may occur.

For example, as described above, when the light receiving area FXA (or the light receiving element OPD) of each of the light sensing pixels PSR receives the second color light (for example, the green light G) emitted from the second sub-pixel SPX2, as the second sub-pixel SPX2 and the light sensing pixel PSR are designed to be disposed adjacent to each other, the second sub-pixel SPX2 and the light sensing pixel PSR may overlap in at least a partial area. In this case, the light emitting layer (for example, the light emitting layer EML of FIG. 5) included in the light emitting element LD of the second sub-pixel SPX2 and the light receiving layer (for example, the light receiving layer OPL of FIG. 5) included in the light receiving element OPD of the light sensing pixel PSR may be formed (or disposed) to overlap in the same layer (for example, the light emitting layer EML and the light receiving layer OPL are formed (or disposed) to be connected (or contacted) to each other). For example, even though different masks are used in a process of forming the light emitting layer (for example, the light emitting layer EML of FIG. 5) included in the light emitting element LD of the second sub-pixel SPX2 and a process of forming light receiving layer (for example, the light receiving layer OPL of FIG. 5) included in the light receiving element OPD of the light sensing pixel PSR, the light emitting layer EML and the light receiving layer OPL may be formed (or disposed) to be connected (or contacted) to each other at least a partial area of the pixel defining layer (for example, the pixel defining layer PDL of FIG. 5) due to a process error or the like. In this case, reliability of the display device DD (for example, reliability or the like of image display and/or fingerprint sensing of the display device DD) may be reduced.

In addition, as the sub-pixels SPX1, SPX2, and SPX3 and the light sensing pixels PSR are designed to be disposed adjacent to each other, a current leakage phenomenon in which a current flows from the cathode electrode (for example, the cathode electrode CE of FIG. 5) included in the light emitting element LD of each of the sub-pixels SPX to the second sensor electrode (for example, the second sensor electrode UE of FIG. 5) included in the light receiving element OPD of each of the light sensing pixels PSR may occur. In this case, noise may occur when the light sensing pixels PSR recognizes a pattern of the user's fingerprint by sensing light reflected by the external object (for example, the user's finger or the like).

Accordingly, the display device DD according to embodiments of the disclosure may include the partition wall member BK disposed in each unit pixel UPX.

In an embodiment, the partition wall member BK may be disposed in a shape surrounding the light sensing pixels PSR (or the light receiving area FXA of the light sensing pixels PSR) on a plane (for example, on the plane according to the first direction DR1 and the second direction DR2).

In an embodiment, the partition wall members BK may be disposed between the light sensing pixels PSR (for example, the light receiving areas FXA of the light sensing pixels PSR) and the first and third sub-pixels SPX1 and SPX3 or the light emitting areas EMA of the first and third sub-pixels SPX1 and SPX3. For example, the partition wall members BK may be spaced apart from the light sensing pixels PSR, the first sub-pixel SPX1, and the second sub-pixel SPX2 along the first direction DR1.

In an embodiment, the partition wall members BK may be disposed to overlap the second sub-pixels SPX2 in at least a partial area. For example, the partition wall members BK may be spaced apart from the light sensing pixels PSR along the second direction DR2 and may overlap the second sub-pixels SPX2 in at least a partial area.

Here, as described with reference to FIG. 5, the partition wall member BK may have the reverse tapered shape. Accordingly, in a manufacturing process, since the light emitting layer (for example, the light emitting layer EML of FIG. 5) of the second sub-pixel SPX2 and the light receiving layer (for example, the light receiving layer OPL of FIG. 5) of the light sensing pixel PSR are formed (or disposed) after the partition wall member BK is formed (or disposed), even though the second sub-pixel SPX2 and the light sensing pixel PSR are disposed adjacent to each other, the light emitting layer EML and the light receiving layer OPL may be formed (or disposed) to be separated from each other without being connected (or contacted) to each other.

In addition, in a case of configurations formed using a common mask among configurations (for example, the second electrode layer E2 and the like of FIG. 5) formed after the partition wall member BK is formed in the manufacturing process, even though the common mask is used, the configurations formed using the common mask may be disposed to be separated from each other by the partition wall member BK.

However, when the second electrode layer (for example, the second electrode layer E2 of FIG. 5) among configurations formed as a common electrode layer is completely separated by the partition wall member BK, that is, when the second sensor (for example, the second sensor electrode UE of FIG. 5) of the light sensing pixels PSR and the cathode electrode (for example, the cathode electrode CE of FIG. 5) of the sub-pixels SPX are completely separated, the light sensing pixel PSR (for example, the second sensor electrode UE of the light sensing pixel PSR) surrounded by the partition wall member BK may be disconnected from the second power line PL2 (refer to FIG. 4), and thus, the light sensing pixel PSR may not obtain the voltage of the second driving power VSS (refer to FIG. 4).

Accordingly, the partition wall member BK according to embodiments of the disclosure may include an opening area at least partially opened on a plane so that the second sensor electrode (for example, the second sensor electrode UE of FIG. 5) of the light sensing pixels PSR and the cathode electrode (for example, the cathode electrode CE of FIG. 5) of the sub-pixels SPX may be formed in an interconnected form. For example, a portion of the partition wall member BK may include an end opened to the pixel defining layer (for example, the pixel defining layer PDL of FIG. 5) of a bank area BA.

For example, the partition wall member BK may include a first partition wall member BK1 and a second partition wall member BK2. The first partition wall member BK1 and the second partition wall member BK2 may be alternately disposed along the second direction DR2 on the same column (for example, the second column C2 or the fourth column C4) in which the light sensing pixels PSR and the second sub-pixels SPX2 are positioned. In addition, the first partition wall member BK1 and the second partition wall member BK2 may be spaced apart from each other. Accordingly, the partition wall member BK may include an opening area SOP partially opened on a plane. In FIGS. 6A and 6B, the partition wall member BK includes two opening areas SOP, but embodiments of the disclosure are not limited thereto. For example, the partition wall member BK may be opened on only one side surface on a plane to include one opening area SOP.

A shape of the partition wall member BK may be variously formed. For example, as shown in FIGS. 6A and 6B, the partition wall member BK may have a substantially quadrangular (for example, rectangular) shape on a plane. For example, each of the first partition wall member BK1 and the second partition wall member BK2 may have a quadrangular shape of which one side is opened, and the first partition wall member BK1 and the second partition wall member BK2 may be symmetrical with respect to a line (for example, the second row R2) parallel to the first direction DR1 and disposed in a shape in which the opened sides face each other. For example, the first partition wall member BK1 and the second partition wall member BK2 may be spaced apart from each other with the light sensing pixel PSR interposed therebetween. Accordingly, the opening area SOP of the partition wall member BK may be formed in a direction facing the first sub-pixel SPX1 and the third sub-pixel SPX3. However, this is an example, and the shape of the partition wall member BK is not limited thereto. For example, according to embodiments, the partition wall member BK may have various shapes in addition to the shape shown in FIGS. 6A and 6B.

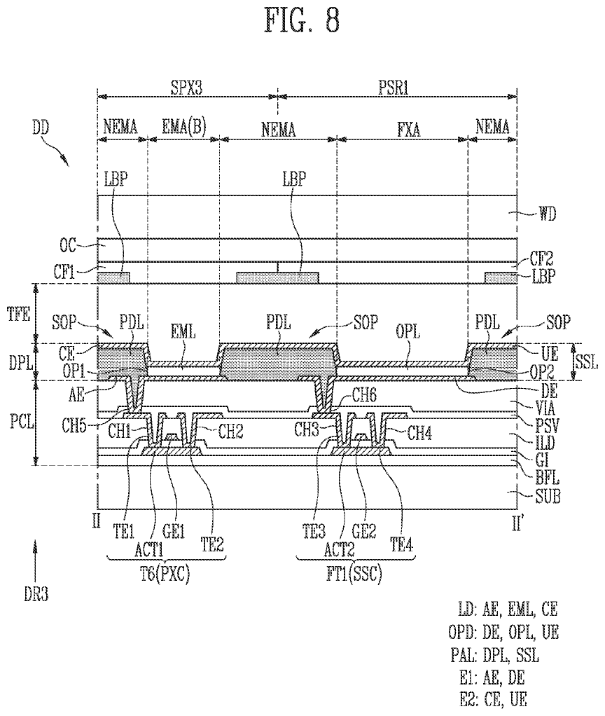

Hereinafter, a stack structure of the sub-pixels SPX1, SPX2, and SPX3 including the light emitting element LD, the light sensing pixels PSR including the light receiving device OPD, and the partition wall member BK is mainly described with reference to FIGS. 7 and 8.

FIG. 7 is a cross-sectional view taken along a line I-I′ of FIG. 6A according to embodiments of the disclosure. FIG. 8 is a cross-sectional view taken along a line II-IF of FIG. 6A according to embodiments of the disclosure.

In FIGS. 7 and 8, “formed and/or disposed on the same layer” may mean formed in the same process (or same step), and “formed and/or disposed on different layers” may mean formed in different processes (or different steps).

For convenience of description, in FIG. 7, a cross-sectional structure of the sub-pixel and the light sensing pixel is described using the second sub-pixel SPX2 among the sub-pixels SPX1, SPX2, and SPX3 and the second light sensing pixel PSR2 among the light sensing pixels PSR as an example. In FIG. 8, a cross-sectional structure of the sub-pixel and the light sensing pixel is described using the third sub-pixel SPX3 among the sub-pixels SPX1, SPX2, and SPX3 and the first light sensing pixel PSR1 among the light sensing pixels PSR as an example.

In addition, in FIGS. 7 and 8, only a cross-sectional structure of a portion corresponding to the sixth transistor T6 among the first to seventh transistors T1 to T7 shown in FIG. 4 and a cross-sectional structure of a portion corresponding to the first sensor transistor FT1 among the first to third sensor transistors FT1 to FT3 are shown.

In addition, in FIGS. 7 and 8, a height direction (or a vertical direction) on a cross-section is shown as the third direction DR3.

In FIGS. 7 and 8, for convenience of explanation, a further description of components and technical aspects previously described may be omitted, and differences will be mainly described.

First, referring to FIGS. 1 to 7, the display device DD includes the sub-pixel (for example, the second sub-pixel SPX2) and the light sensing pixel (for example, the second light sensing pixel PSR2) disposed on the substrate SUB.

The substrate SUB may include a transparent insulating material, and thus, transmission of light may be possible. The substrate SUB may be a rigid substrate or a flexible substrate.

The rigid substrate may be, for example, one of a glass substrate, a quartz substrate, a glass ceramic substrate, and a crystalline glass substrate.

The flexible substrate may be, for example, one of a film substrate and a plastic substrate including a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate.

The circuit layer PCL (for example, the pixel circuit PXC) of the second sub-pixel SPX2 and the circuit layer PCL (for example, the sensor circuit SSC) of the second light sensing pixel PSR2 may be disposed on the substrate SUB. The circuit layer PCL may include a buffer layer BFL, a gate insulating layer GI, an interlayer insulating layer ILD, a passivation layer PSV, and a via layer VIA sequentially stacked on the substrate SUB along the third direction DR3.

The buffer layer BFL may prevent an impurity from diffusing into the sixth transistor T6 included in the pixel circuit PXC and the first sensor transistor FT1 included in the sensor circuit SSC. The buffer layer BFL may be an inorganic insulating layer including an inorganic material. The buffer layer BFL may include at least one of a metal oxide such as, for example, silicon nitride (SiNx), silicon oxide (SiOx), silicon oxynitride (SiOxNy), and/or aluminum oxide (AlOx). The buffer layer BFL may be provided as a single layer, but may also be provided as multiple layers of at least double layers. When the buffer layer BFL is provided in multiple layers, each layer may be formed of the same material or different materials. The buffer layer BFL may be omitted according to a material, a process condition, and the like of the substrate SUB.

A semiconductor layer (or a semiconductor pattern) including a first active pattern ACT1 and a second active pattern ACT2 may be disposed on the buffer layer BFL. The semiconductor layer may include a polysilicon semiconductor. For example, the semiconductor layer may be formed through a low-temperature poly-silicon (LTPS) process. However, embodiments of the disclosure are not limited thereto, and at least a portion of the semiconductor layer may be formed of an oxide semiconductor, a metal oxide semiconductor, or the like according to embodiments.

Each of the first and second active patterns ACT1 and ACT2 may include a channel area (or channel region), a first contact area connected to one end of the channel area, and a second contact area connected to another end of the channel area. The channel area, the first contact area, and the second contact area may be formed of a semiconductor layer that is not doped with an impurity or that is doped with an impurity. For example, the first contact area and the second contact area may be formed of a semiconductor layer doped with an impurity, and the channel area may be formed of a semiconductor layer that is not doped with an impurity. As an impurity, for example, a p-type impurity may be used, but the impurity is not limited thereto. One of the first and second contact areas may be a source area (or source region), and the other may be a drain area (or drain region).

The gate insulating layer GI may be provided and/or formed entirely on the first and second active patterns ACT1 and ACT2 and the buffer layer BFL.

The gate insulating layer GI may be an inorganic layer (or an inorganic insulating layer) including an inorganic material. For example, the gate insulating layer GI may include at least one of a metal oxide such as silicon nitride (SiNx), silicon oxide (SiOx), silicon oxynitride (SiOxNy), and/or aluminum oxide (AlOx). However, a material of the gate insulating layer GI is not limited to the above-described embodiments. According to an embodiment, the gate insulating layer GI may be formed of an organic layer (or an organic insulating layer) including an organic material. The gate insulating layer GI may be provided as a single layer, but may also be provided as multiple layers of at least double layers. A first gate electrode GE1 and a second gate electrode GE2 may be provided and/or

formed on the gate insulating layer GI. The first gate electrode GE1 may be provided and/or formed on the gate insulating layer GI to correspond to the channel area of the first active pattern ACT1, and the second gate electrode GE2 may be provided and/or formed on the gate insulating layer GI to correspond to the channel area of the second active pattern ACT2. The first and second gate electrodes GE1 and GE2 may be formed as a single layer with a material of a group selected from, for example, copper (Cu), molybdenum (Mo), tungsten (W), aluminum neodymium (AlNd), titanium (Ti), aluminum (Al), silver (Ag), and an alloy thereof in alone or combination, or may be formed as double layers or multiple layers of, for example, molybdenum (Mo), titanium (Ti), copper (Cu), aluminum (Al), or silver (Ag), which is a low-resistance material, in order to reduce a line resistance.

The interlayer insulating layer ILD may be provided and/or formed entirely on the first and second gate electrodes GE1 and GE2 and the gate insulating layer GI.

The interlayer insulating layer ILD may include the same material as the gate insulating layer GI, or may include one or more materials selected from materials exemplified as the configuration material of the gate insulating layer GI.

First, second, third, and fourth connection members TE1, TE2, TE3, and TE4 may be provided and/or formed on the interlayer insulating layer ILD.

The first, second, third, and fourth connection members TE1, TE2, TE3, and TE4 may be spaced apart from each other on the interlayer insulating layer ILD.

The first connection member TE1 may contact the first contact area of one end of the first active pattern ACT1 through a first contact hole CH1 formed in the interlayer insulating layer ILD and the gate insulating layer GI. When the first contact area is a source area, the first connection member TE1 may be a first source electrode.

The second connection member TE2 may contact the second contact area of the other end of the first active pattern ACT1 through a second contact hole CH2 formed in the interlayer insulating layer ILD and the gate insulating layer GI. When the second contact area is a drain area, the second connection member TE2 may be a first drain electrode.

The third connection member TE3 may contact the first contact area at one end of the second active pattern ACT2 through a third contact hole CH3 formed in the interlayer insulating layer ILD and the gate insulating layer GI. When the first contact area is a source area, the third connection member TE3 may be a second source electrode.

The fourth connection member TE4 may contact the second contact area of the other end of the second active pattern ACT2 through a fourth contact hole CH4 formed in the interlayer insulating layer ILD and the gate insulating layer GI. When the second contact area is a drain area, the fourth connection member TE4 may be a second drain electrode.

The first to fourth connection members TE1 to TE4 may include the same material as the first and second gate electrodes GE1 and GE2 or may include one or more materials selected from the materials exemplified as the configuration material of the first and second gate electrodes GE1 and GE2.

The passivation layer PSV may be provided and/or formed entirely on the first to fourth connection members TE1 to TE4 and the interlayer insulating layer ILD.

The passivation layer PSV (or a protective layer) may be an inorganic layer (or an inorganic insulating layer) including an inorganic material or an organic layer (or an organic insulating layer) including an organic material. The inorganic layer may include, for example, at least one of a metal oxide such as silicon oxide (SiOx), silicon nitride (SiNx), silicon oxynitride (SiOxNy), and/or aluminum oxide (AlOx). The organic layer may include at least one of, for example, acrylic resin (polyacrylates resin), epoxy resin, phenolic resin, polyamides resin, polyimide resin, unsaturated polyesters resin, poly-phenylen ethers resin, poly-phenylene sulfides resin, and/or benzocyclobutene resin.

According to an embodiment, the passivation layer PSV may include the same material as the interlayer insulating layer ILD, but is not limited thereto. The passivation layer PSV may be provided as a single layer, but may also be provided as multiple layers of at least double layers.

The passivation layer PSV may be partially opened to include a fifth contact hole CH5 exposing one area of the first connection member TE1 and a sixth contact hole CH6 exposing one area of the third connection member TE3.

The via layer VIA may be provided and/or formed entirely on the passivation layer PSV.

The via layer VIA may be partially opened to include fifth and sixth contact holes CH5 and CH6 respectively corresponding to the fifth and sixth contact holes CH5 and CH6 of the passivation layer PSV. The via layer VIA may include the same material as the passivation layer PSV or may include one or more materials selected from the materials exemplified as the configuration material of the passivation layer PSV. In an embodiment, the via layer VIA may be an organic layer formed of an organic material.

In FIG. 7, the via layer VIA is disposed on the passivation layer PSV, but is not limited thereto. According to an embodiment, one layer of the passivation layer PSV and the via layer VIA may be omitted.

The pixel element layer PAL may be disposed on the circuit layer PCL. For example, the display element layer DPL may be provided and/or formed on the circuit layer PCL (for example, the pixel circuit PXC) of the second sub-pixel SPX2, and the sensor layer SSL may be provided and/or formed on the circuit layer PCL (for example, the sensor circuit SSC) of the second light sensing pixel PSR2.

The display element layer DPL may include the light emitting element LD and the pixel defining layer PDL. The light emitting element LD may include the anode electrode AE (or a first pixel electrode), the light emitting layer EML, and the cathode electrode CE (or a second pixel electrode). The light emitting element LD may be electrically connected to the sixth transistor T6 of the pixel circuit PXC.

The sensor layer SSL may include the light receiving element OPD and the pixel defining layer PDL. The light receiving element OPD may be used to implement an optical fingerprint sensor. For example, the light receiving element OPD may be formed of a photo diode, a complementary metal-oxide-semiconductor (CMOS) image sensor, a charge coupled device (CCD) camera, a photo transistor, or the like, but is not limited thereto. The light receiving element OPD may recognize a fingerprint by sensing light reflected by the external object (for example, the user's finger or the like). For example, when the user's finger touches the window WD, light output from the light emitting element LD (or the light emitting layer EML) may be reflected by a ridge or a valley of the finger, and the reflected light may reach the light receiving element OPD (or the light receiving layer OPL) of the sensor layer SSL. The light receiving element OPD may recognize the pattern of the user's fingerprint by distinguishing the light reflected from the ridge of the finger and the light reflected from the valley of the finger.

The light receiving element OPD may be electrically connected to the first sensor transistor FT1 of the sensor circuit SSC. The light receiving element OPD may include the first sensor electrode DE, the light receiving layer OPL (or a photoelectric conversion layer), and the second sensor electrode UE.

The anode electrode AE and the first sensor electrode DE may be formed of a metal layer of, for example, Ag, Mg, Al, Pt, Pd, Au, Ni, Nd, Ir, Cr, an alloy thereof, and the like, indium tin oxide (ITO), indium zinc oxide (IZO), zinc oxide (ZnOx), indium tin zinc oxide (ITZO), and/or the like. The anode electrode AE may be electrically connected to the sixth transistor T6 through the fifth contact hole CH5 formed in the via layer VIA and the passivation layer PSV. The first sensor electrode DE may be electrically connected to the first sensor transistor FT1 through the sixth contact hole CH6 formed in the via layer VIA and the passivation layer PSV.

The anode electrode AE of the second sub-pixel SPX2 and the first sensor electrode DE of the second light sensing pixel PSR2 may configure the first electrode layer E1. For example, the anode electrode AE and the first sensor electrode DE may be simultaneously formed by the same process using a mask, but the disclosure is not limited thereto.

The pixel defining layer PDL (or a bank PDL) may be provided and/or formed entirely on the anode electrode AE, the first sensor electrode DE, and the via layer VIA.

The pixel defining layer PDL may define (or partition) the light emitting area EMA of the second sub-pixel SPX2 and the light receiving area FXA of the second light sensing pixel PSR2. The pixel defining layer PDL may be an organic insulating layer formed of an organic material. The organic material may include, for example, an acrylic resin, an epoxy resin, a phenolic resin, a polyamide resin, a polyimide resin, and the like.

According to an embodiment, the pixel defining layer PDL may include a light absorbing material or a light absorbing agent may be applied to the pixel defining layer PDL. Therefore, the pixel defining layer PDL may serve to absorb light input from outside of the display device DD. For example, the pixel defining layer PDL may include a carbon-based black pigment. However, embodiments of the disclosure are not limited thereto, and according to embodiments, the pixel defining layer PDL may include, for example, an opaque metal material such as chromium (Cr), molybdenum (Mo), an alloy (MoTi) of molybdenum (Mo) and titanium (Ti), tungsten (W), vanadium (V), niobium (Nb), tantalum (Ta), manganese (Mn), cobalt (Co), or nickel (Ni) having a high light absorption factor.

The pixel defining layer PDL may include a first opening OP1 exposing one area (for example, a portion of an upper surface) of the anode electrode AE and a second opening OP2 exposing one area (for example, a portion of an upper surface) of the first sensor electrode DE, and may protrude in the third direction DR3 from the via layer VIA along a perimeter of the light emitting area EMA and the light receiving area FXA.

The first opening OP1 of the pixel defining layer PDL may correspond to the light emitting area EMA, and the second opening OP2 of the pixel defining layer PDL may correspond to the light receiving area FXA. The pixel defining layer PDL may be patterned to include the first opening OP1 of a polygon (for example, a quadrangle, a hexagon, or the like) so that the light emitting area EMA of the second sub-pixel SPX2 has a planar shape of a polygon (for example, quadrangle, hexagon, or the like) in a process using a mask. In addition, the pixel defining layer PDL may be patterned to include the second opening OP2 of a quadrangle (for example, a rectangle, a square, or the like) so that the light receiving area FXA of the second light sensing pixel PSR2 has a planar shape of a quadrangle (for example, a rectangle, a square, or the like) in the above-described process.

In an embodiment, the partition wall member (for example, the first partition wall member BK1) may be formed on the pixel defining layer PDL.

In an embodiment, as described with reference to FIG. 5, the first partition wall member BK1 may have the reverse taper shape.

According to embodiments, the first partition wall member BK1 may include substantially the same material as the pixel defining layer PDL. For example, the first partition wall member BK1 may be an organic insulating layer formed of an organic material. The organic material may include, for example, an acryl resin, an epoxy resin, a phenolic resin, a polyamide resin, a polyimide resin, and the like.

According to embodiments, the first partition wall member BK1 may include a light absorbing material or a light absorbing agent may be applied to the first partition wall member BK1. Therefore, the first partition wall member BK1 may serve to absorb light input from outside of the display device DD. For example, the first partition wall member BK1 may include a carbon-based black pigment. However, embodiments of the disclosure are not limited thereto, and the first partition wall member BK1 may include, for example, an opaque metal material such as chromium (Cr), molybdenum (Mo), an alloy (MoTi) of molybdenum (Mo) and titanium (Ti), tungsten (W), vanadium (V), niobium (Nb), tantalum (Ta), manganese (Mn), cobalt (Co), or nickel (Ni) having a high light absorption factor.

The light emitting layer EML may be provided and/or formed on the anode electrode AE exposed by the first opening OP1 of the pixel defining layer PDL. The light emitting layer EML may include an organic material such that the light emitting layer EML emits light of a predetermined color (for example, the green light G). For example, the light emitting layer EML may include a hole transport layer, an organic material layer, and an electron transport layer.

The light receiving layer OPL may be provided and/or formed on the first sensor electrode DE exposed by the second opening OP2 of the pixel defining layer PDL. The light receiving layer OPL may serve to absorb and detect light reflected or scattered from the fingerprint of the user's finger. At this time, the light receiving layer OPL may recognize the fingerprint by sensing a difference of an amount of light reflected or scattered and absorbed from the ridge or the valley of the fingerprint of the user's finger. A hole and an electron generated by absorbing light by the light receiving layer OPL may be transferred to the cathode electrode CE and the second sensor electrode UE, respectively.

The light receiving layer OPL may be formed of an organic photosensitive material. For example, the organic photosensitive material may include a dithiolene-based material (BDN) (bis(4-dimethylaminodithiobenzyl)nickel(II)), a benzotriazole-based high molecular compound (PTZBTTT-BDT), a porphyrin-based small molecule material (DHTBTEZP), and the like, but is not limited thereto.

The electron transport layer may be disposed on the light emitting layer EML and the light receiving layer OPL.

As described above, a case where at least a portion of the light emitting layer EML and at least a portion of the light receiving layer OPL are provided and/or formed on the pixel defining layer PDL due to a process error or the like may occur.

For example, even though a mask corresponding to a size of the light emitting area EMA (or a size of the first opening OP1 of the pixel defining layer PDL) is used in a process of forming (or disposing) the light emitting layer EML, the light emitting layer EML may be formed in at least a partial area on the non-light emitting area NEMA except for the light emitting area EMA due to a process error or the like. For example, the light emitting layer EML may be provided and/or formed on the anode electrode AE exposed by the first opening OP1 and may also be provided and/or formed on at least a portion of the pixel defining layer PDL. Hereinafter, for convenience of description, a portion of the light emitting layer EML formed on the pixel defining layer PDL is referred to as a first intermediate layer ML1 (for example, the first intermediate layer ML1 is formed on the pixel defining layer PDL and integrally formed with the light emitting layer EML).

In addition, even though a mask corresponding to a size of the light receiving area FXA (or a size of the second opening OP2 of the pixel defining layer PDL) is used in a process of forming (or disposing) the light receiving layer OPL, the light receiving layer OPL may be formed in at least a partial area on the non-light emitting area NEMA except for the light receiving area FXA due to a process error or the like. For example, the light receiving layer OPL may be provided and/or formed on the first sensor electrode DE exposed by the second opening OP2 and may also be provided and/or formed in at least a portion of the pixel defining layer PDL. Hereinafter, for convenience of description, a portion of the light receiving layer OPL formed on the pixel defining layer PDL is referred to as a second intermediate layer ML2 (for example, the second intermediate layer ML2 is formed on the pixel defining layer PDL and is integrally formed with the light receiving layer OPL).

Since the light emitting layer EML and the light receiving layer OPL are provided and/or formed in the same layer during a manufacturing process, as described with reference to FIGS. 6A and 6B, as the resolution of the display device DD increases, when the sub-pixel (for example, the second sub-pixel SPX2) and the light sensing pixel (for example, the second light sensing pixel PSR2) are designed to be disposed (or positioned) adjacent to each other, a case where the light emitting layer EML of the second sub-pixel SPX2 and the light receiving layer OPL of the second light sensing pixel PSR2 are connected to each other (or contact each other) on the pixel defining layer PDL due to a manufacturing process error or the like may occur.

However, the display device DD according to embodiments of the disclosure may include the partition wall member BK (for example, the first partition wall member BK1) provided and/or formed on the pixel defining layer PDL and having the reverse taper shape. In this case, since the light emitting layer EML and the light receiving layer OPL are formed (or provided) after the first partition wall member BK1 is formed (or provided) in the manufacturing process, even though the first intermediate layer ML1 which is a portion of the light emitting layer EML and the second intermediate layer ML2 which is a portion of the light receiving layer OPL are formed on the pixel defining layer PDL due to a process error or the like of the manufacturing process, the first intermediate layer ML1 (or the light emitting layer EML) and the second intermediate layer ML2 (or the light receiving layer OPL) may be formed (or provided) to be separated from each other without being connected to each other (or contacting each other).

A portion of the light emitting layer EML and/or a portion of the light receiving layer OPL may be deposited (or disposed) on the first partition wall member BK1. For example, a first dummy layer RML1 which is a portion of the light emitting layer EML and/or a portion of the light receiving layer OPL may be formed (or disposed) on the first partition wall member BK1, by the process of forming the light emitting layer EML and the process of forming the light receiving layer OPL.

The cathode electrode CE may be provided and/or formed on the light emitting layer EML of the first sub-pixel SPX1, and the second sensor electrode UE may be provided and/or formed on the light receiving layer OPL of the light sensing pixel PSR.

The cathode electrode CE of the first sub-pixel SPX1 and the second sensor electrode UE of the light sensing pixel PSR may configure the second electrode layer E2. In an embodiment, the cathode electrode CE and the second sensor electrode UE may be a common electrode (for example, the second electrode layer E2) integrally formed in the display area DA. The voltage of the second driving power VSS may be supplied to the cathode electrode CE and the second sensor electrode UE.

The cathode electrode CE and the second sensor electrode UE may be formed of a metal layer of, for example, Ag, Mg, Al, Pt, Pd, Au, Ni, Nd, Jr, Cr, and the like, and/or a transparent conductive layer of, for example, ITO, IZO, ZnO, ITZO, and the like. In an embodiment, the cathode electrode CE and the second sensor electrode UE may be formed of multiple layers of double or more layers including a metal thin layer, and may be formed of, for example, triple layers of ITO/Ag/ITO.

Even in a process of using a common mask when the second electrode layer E2 is formed, as shown in FIG. 7, the cathode electrode CE of the second sub-pixel SPX2 and the second sensor electrode UE of the second light sensing pixel PSR2 may be separated from each other by the partition wall member BK (for example, the first partition wall member BK1) having the reverse taper shape. For example, in the cross-sectional view shown in FIG. 7, since an angle θ formed by a side surface (or an inclined surface) and a lower surface of the first partition wall member BK1 exceeds 90° (for example, θ>90°), a phenomenon in which the second electrode layer E2 becomes disconnected may occur according to a step coverage. That is, when the second electrode layer E2 is formed, the second electrode layer E2 may not dig from a side surface of the first partition wall member BK1 having the reverse taper shape to a lower area, may not be deposited, and thus, the second electrode layer E2 may be disposed and/or deposited in a manner in which portions of the second electrode layer E2 are separated (or disconnected) from each other. Accordingly, even though the second electrode layer E2 is formed through the process using the common mask without a separate patterning process, portions of the second electrode layer E2 may be disposed to be separated from each other by the first partition wall member BK1 having the reverse taper shape. That is, the cathode electrode CE of the second sub-pixel SPX2 and the second sensor electrode UE of the second light sensing pixel PSR2 may be disposed to be separated from each other. A portion of the second electrode layer E2 may be deposited and disposed on the first partition wall member BK1. For example, a second dummy layer RML2 which is a portion of the second electrode layer E2 may be disposed on the first partition wall member BK1 by a process of forming the second electrode layer E2. For example, the second dummy layer RML2 may be formed (or disposed) on the first dummy layer RML1.

As the cathode electrode CE of the first sub-pixel SPX1 and the second sensor electrode UE of the light sensing pixel PSR are disposed to be separated from each other, a current leakage phenomenon in which a current flows from the cathode electrode CE to the second sensor electrode UE may be reduced or eliminated, and noise may be reduced or minimized when the light sensing pixel PSR senses the light reflected by the external object (for example, the user's finger or the like) to recognize the pattern of the user's fingerprint.

As the angle θ formed by the side surface (or the inclined surface) and the lower surface of the first partition wall member BK1 increases, a tendency in which the second electrode layer E2 is disposed to be separated from the first partition wall member BK1 becomes stronger, and thus, a noise reduction effect may be increased or maximized.

In addition, since the cathode electrode CE of the sub-pixel (for example, the second sub-pixel SPX2) and the second sensor electrode UE of the light sensing pixel (for example, the second light sensing pixel PSR2) may be deposited to be separate from each other in a manufacturing process using a common mask by the partition wall member BK (for example, the first partition wall member BK1) without using a separate patterning process, a manufacturing process time may be shortened, and a process cost may be reduced.

In addition, according to embodiments, since the partition wall member BK is further disposed on the pixel defining layer PDL, an optical path is created allowing the light emitted from the light emitting element LD to proceed to an upper portion of the display device DD without directly proceeding to the light receiving element OPD. Accordingly, since the light sensing pixel PSR does not directly receive the light emitted from the light emitting element LD, and may sense the light emitted from the light emitting element LD and reflected by the external object (for example, the user's finger), accuracy in recognizing the pattern of the user's fingerprint by the light sensing pixel PSR may be increased.

However, as described with reference to FIGS. 5 to 6B, the first partition wall member BK1 may include the opening area at least partially opened on the plane (for example, the plane according to the first direction DR1 and the second direction DR2 of FIG. 6A), and thus, the cathode electrode CE and the second sensor electrode UE may be formed in an interconnected form in a partial area.

For example, referring further to FIG. 8, according to embodiments, a partition wall member is not disposed on the pixel defining layer PDL corresponding to the opening areas SOP described with reference to FIG. 6A. That is, as described with reference to FIG. 6A, the partition wall member (for example, the partition wall member BK of FIG. 6A) may include the opening area SOP at least partially opened on the plane. Accordingly, the second sensor electrode UE may be connected to the cathode electrode CE and may receive the voltage of the second driving power VSS through the second power line PL2.

According to embodiments, to prevent or reduce current leakage, a distance of the opening area SOP of the partition wall member BK (for example, a distance along the first direction DR1 of the opening area SOP of FIG. 6A) may be minimized or reduced. For example, in FIG. 6A, the distance along the second direction DR2 of the opening area SOP may be narrower than a distance along the second direction DR2 of sub-pixel (for example, the first sub-pixel SPX1 or the third sub-pixel SPX3) adjacent to the opening area SOP along the first direction DR1. However, this is merely an example, and the distance of the opening area SOP of the partition wall member BK may be variously set.

Referring to FIG. 7 again, the thin film encapsulation layer TFE may be provided and/or formed entirely on the cathode electrode CE, the second sensor electrode UE, and the second dummy layer RML2.

Since the thin film encapsulation layer TFE corresponds to the same configuration as the thin film encapsulation layer TFE described with reference to FIG. 5, a description thereof is omitted for convenience of explanation.

A light blocking pattern LBP may be provided and/or formed on the thin film encapsulation layer TFE to correspond to the non-light emitting area NEMA of the second sub-pixel SPX2 and the non-light emitting area NEMA of the second light sensing pixel PSR2.

The light blocking pattern LBP may include a light blocking material that prevents or reduces a light leakage defect in which light (or rays) is leaked between the second sub-pixel SPX2 and a sub-pixel adjacent thereto. For example, the light blocking pattern LBP may include a black matrix, but is not limited thereto. According to an embodiment, the light blocking pattern LBP may include at least one of carbon black (CB) and titanium black (TiBK). In addition, the light blocking pattern LBP may prevent or reduce color mixing of light emitted from each of the second sub-pixel SPX2 and the sub-pixels adjacent thereto.

In the second sub-pixel SPX2, the light blocking pattern LBP may be partially opened so as not to overlap the light emitting area EMA. An opening of the light blocking pattern LBP may provide an optical path so that the light emitted from the light emitting element LD may proceed to an upper portion of the display device DD. To this end, the opening of the light blocking pattern LBP may be disposed to overlap the light emitting element LD (or the light emitting area EMA).

In the second light sensing pixel PSR2, the light blocking pattern LBP may be partially opened so as not to overlap the light receiving area FXA. An opening of the light blocking pattern LBP may provide an optical path so that the light reflected from the fingerprint of the user's finger may proceed to the light receiving element OPD. To this end, the opening of the light blocking pattern LBP may be disposed to overlap the light receiving element OPD (or the light receiving area FXA).

Color filters CF1 and CF2 may be disposed on the light blocking pattern LBP and the thin film encapsulation layer TFE.

The color filters CF1 and CF2 may include a first color filter CF1 positioned on at least one surface of the light blocking pattern LBP and the thin film encapsulation layer TFE of the second sub-pixel SPX2 and a second color filter CF2 positioned on at least one surface of the light blocking pattern LBP and the thin film encapsulation layer TFE of the second light sensing pixel PSR2. Hereinafter, the light blocking pattern LBP of the second sub-pixel SPX1 is referred to as a first light blocking pattern, and the light blocking pattern LBP of the light sensing pixel PSR is referred to as a second light blocking pattern.

The first color filter CF1 may be disposed in the opening of the first blocking pattern LBP to directly contact the thin film encapsulation layer TFE exposed through the opening of the first light blocking pattern LBP. The first color filter CF1 may be disposed to overlap the light emitting element LD (or the light emitting area EMA). For convenience of description, only the second sub-pixel SPX2 is shown in FIG. 7, and the first color filter CF1 may be a green color filter. According to embodiments, the first color filter CF1 may further include each of a red color filter overlapping the light emitting area EMA of the first sub-pixel SPX1 and a blue color filter overlapping the light emitting area EMA of the third sub-pixel SPX3. For example, in FIG. 8, the first color filter CF1 overlapping the light emitting area EMA of the third sub-pixel SPX3 may include the blue color filter.

The second color filter CF2 may be disposed in the opening of the second light blocking pattern LBP to directly contact the thin film encapsulation layer TFE exposed through the opening of the second light blocking pattern LBP. The second color filter CF2 may be disposed to overlap the light receiving element OPD (or the light receiving area FXA). The second color filter CF2 may include one of a red color filter, a green color filter, and a blue color filter according to a color light sensed by the light receiving layer OPL. For example, when the light receiving layer OPL absorbs light of a green wavelength band, the second color filter CF2 may be a green filter.

The above-described light blocking pattern LBP and color filters CF1 and CF2 may be used as an anti-reflection layer that blocks external light reflection. Since the display device DD (or the display panel DP) includes the light blocking pattern LBP and the color filters CF1 and CF2 used as the anti-reflection layer, in embodiments, a separate polarization layer is not provided. Accordingly, a luminance may be prevented from being reduced and a thickness of the display device DD may be minimized or reduced.

In addition, since the light receiving element OPD is formed on the same layer as the light emitting element LD, the thickness of the display device DD may be further reduced. In addition, since an incident amount of external light to the light receiving element OPD is increased, light sensing performance may be increased. In addition, since the sensor circuit SSC is simultaneously formed during a manufacturing process of the pixel circuit PXC and the light receiving element OPD is simultaneously formed during a manufacturing process of the light emitting element LD, a process time and a manufacturing cost of the display device DD may be reduced.

A planarization layer OC may be further disposed between the first and second color filters CF1 and CF2 and the window WD. The planarization layer OC may serve to planarize a step difference due to configurations disposed thereunder. The planarization layer OC may be an organic layer. The organic layer may include, for example, an acryl resin, an epoxy resin, a phenolic resin, a polyamide resin, or a polyimide resin, but is not limited to.

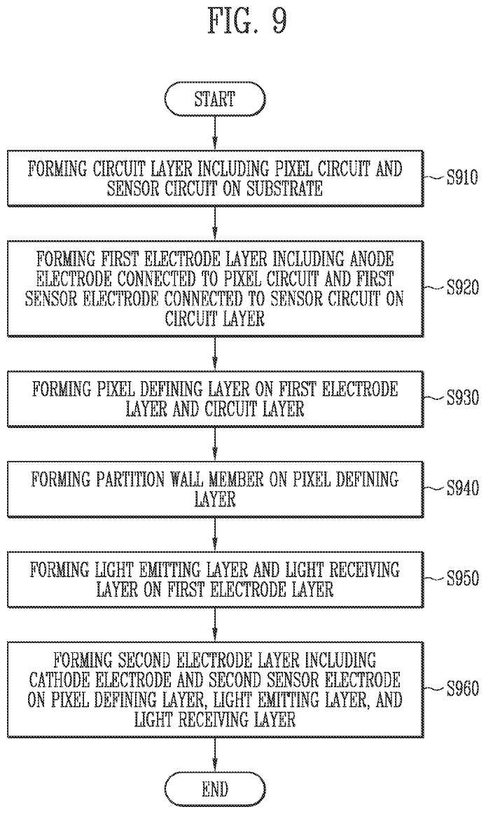

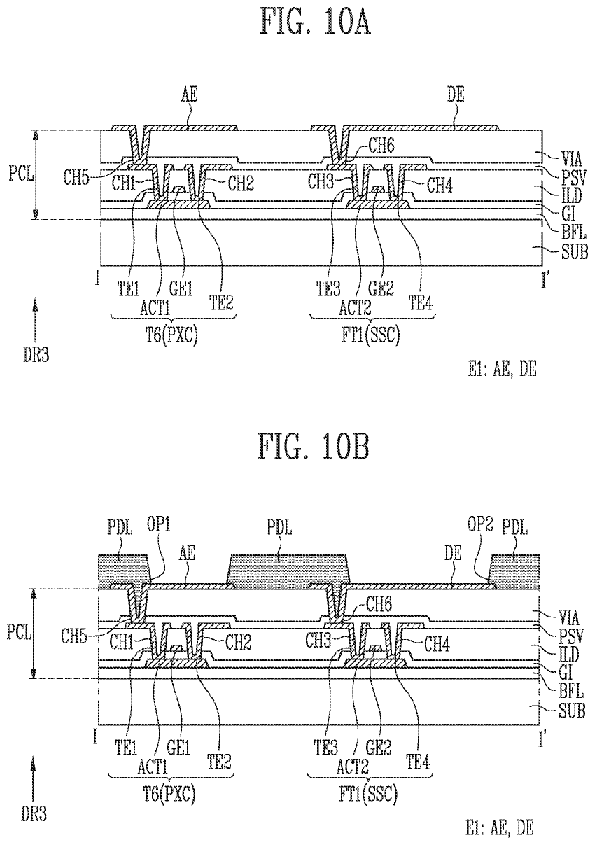

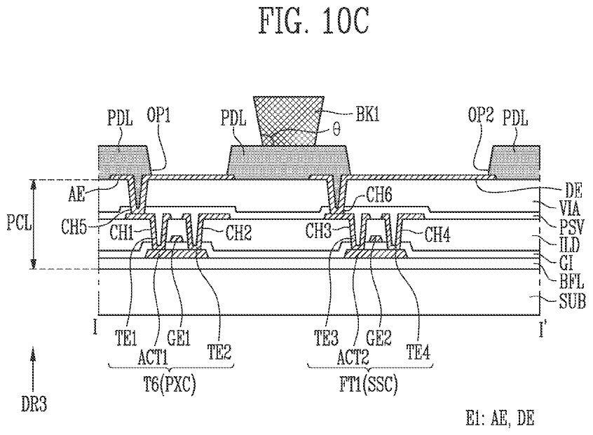

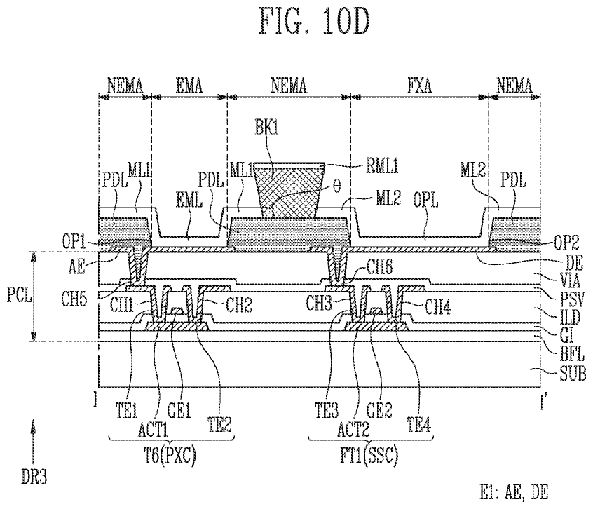

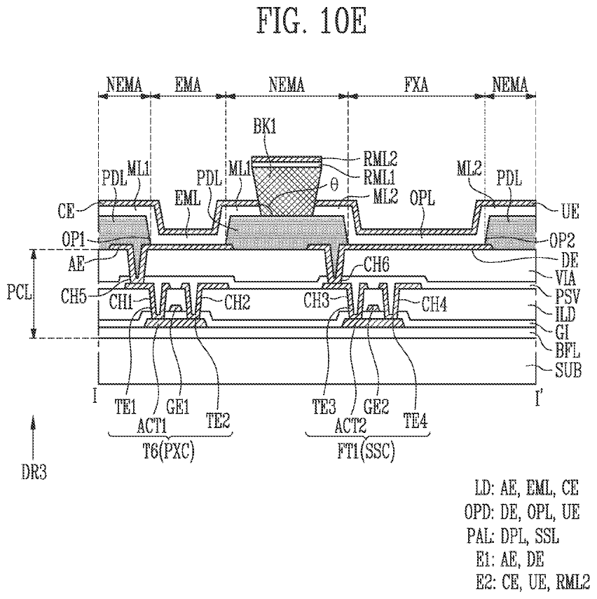

FIG. 9 is a flowchart illustrating a method of manufacturing a display device according to embodiments of the disclosure. FIGS. 10A to 10E are cross-sectional views illustrating the method of manufacturing the display device of FIG. 9 according to embodiments of the disclosure. For convenience of explanation, a further description of components and technical aspects previously described may be omitted.

Referring to FIG. 9, a method of manufacturing the display device according to embodiments of the disclosure may include forming a circuit layer including a pixel circuit and a sensor circuit on a substrate (S910), forming a first electrode layer including an anode electrode connected to the pixel circuit and a first sensor electrode connected to the sensor circuit on the circuit layer (S920), forming a pixel defining layer on the first electrode layer and the circuit layer (S930), forming a partition wall member on the pixel defining layer (S940), forming a light emitting layer and a light receiving layer on the first electrode layer (S950), and forming a second electrode layer including a cathode electrode and a second sensor electrode on the pixel defining layer, the light emitting layer, and the light receiving layer (S960).

First, further referring to FIG. 10A, the method of manufacturing the display device may include forming the circuit layer PCL including the pixel circuit PXC and the sensor circuit SSC on the substrate SUB (S910). Here, the circuit layer PCL may be the circuit layer PCL described with reference to FIGS. 5 to 8.

Thereafter, the method of manufacturing the display device may include forming the first electrode layer E1 including the anode electrode AE connected to the pixel circuit PXC and the first sensor electrode DE connected to the sensor circuit SSC on the circuit layer PCL (S920). For example, as described with reference to FIGS. 5 to 8, the method of manufacturing the display device may include forming the first electrode layer E1 through the same process with the same material.

Referring further to FIG. 10B, thereafter, the method of manufacturing the display device may include forming the pixel defining layer PDL on the first electrode layer E1 and the circuit layer PCL (S930). Here, as described with reference to FIGS. 5 to 8, the pixel defining layer PDL may be provided and/or formed entirely on the anode electrode AE and the first sensor electrode DE of the first electrode layer E1, and the light emitting area EMA and the light receiving area FXA may be defined (or partitioned) by the pixel defining layer PDL.

Referring further to FIG. 10C, thereafter, the method of manufacturing the display device may include forming the partition wall member (for example, the first partition wall member BK1) on the pixel defining layer PDL (S940). In an embodiment, as described with reference to FIGS. 5 to 8, the first partition wall member BK1 may have the reverse taper shape and may include the opening area SOP at least partially opened on the plane (for example, the plane according to the first direction DR1 and the second direction DR2).

Referring further to FIG. 10D, thereafter, the method of manufacturing the display device may include forming the light emitting layer EML and the light receiving layer OPL on the first electrode layer E1 (S950). For example, as described with reference to FIGS. 5 to 8, the light emitting layer EML may be provided and/or formed on the anode electrode AE exposed by the first opening OP1 of the pixel defining layer PDL, and the light receiving layer OPL may be provided and/or formed on the first sensor electrode DE exposed by the second opening OP2 of the pixel defining layer PDL.

In this case, as described with reference to FIGS. 5 to 8, at least a portion of the light emitting layer EML may be formed on at least a partial area of the non-light emitting area NEMA (for example, the pixel defining layer PDL) adjacent to the light emitting area EMA, and thus, the first intermediate layer ML1 may be provided and/or formed. In addition, at least a portion of the light receiving layer OPL may be formed on at least a partial area of the non-light emitting area NEMA (for example, the pixel defining layer PDL) adjacent to the light receiving area FXA, and thus, the second intermediate layer ML2 may be provided and/or formed. In this case, the first intermediate layer ML1 (or the light emitting layer EML) and the second intermediate layer ML2 (or the light receiving layer OPL) may be formed (or provided) to be separated from each other without being connected (or contacted) to each other by the first partition wall member BK1 having the reverse taper shape.

In forming the light emitting layer EML and the light receiving layer OPL (S950), the first dummy layer RML1, which is a portion of the light emitting layer EML and/or a portion of the light receiving layer OPL, may be provided and/or formed on the partition wall member (for example, the first partition wall member BK1).

Referring to FIG. 10E, thereafter, the method of manufacturing the display device may include forming the second electrode layer E2 including the cathode electrode CE and the second sensor electrode UE on the pixel defining layer PDL, the light emitting layer EML, and the light receiving layer OPL (S960). For example, as described with reference to FIGS. 5 to 8, the cathode electrode CE and the second sensor electrode UE of the second electrode layer E2 may be simultaneously formed using a common mask. In this case, the cathode electrode CE and the second sensor electrode UE of the second electrode layer E2 may be disposed to be separated from each other with respect to the first partition wall member BK1 by the first partition wall member BK1 having the reverse taper shape. Accordingly, current leakage from the cathode electrode CE to the second sensor electrode UE may be minimized or reduced, and thus, noise may be minimized or reduced when the light sensing pixel PSR recognizes the pattern of the user's fingerprint by sensing the light reflected by the external object (for example, the user's finger or the like).

In addition, in the method of manufacturing the display device according to embodiments of the disclosure, the cathode electrode CE of the sub-pixel (for example, the second sub-pixel SPX2) and the second sensor electrode UE of the light sensing pixel (for example, the second light sensing pixel PSR2) may be deposited to be separated from each other through a process using a common mask without using a separate patterning process, a manufacturing process time may be shortened, and a process cost may be reduced.

In addition, as described with reference to FIGS. 5 to 8, as the first partition wall member BK1 includes the opening area SOP at least partially opened on the plane (for example, the plane according to the first direction DR1 and the second direction DR2 of FIG. 6A), the cathode electrode CE and the second sensor electrode UE may be formed in an interconnected form in a partial area. Therefore, the second sensor electrode UE (or the cathode electrode CE) may receive the voltage of the second driving power VSS through the second power line PL2.

In forming the second electrode layer E2 (S960), the second dummy layer RML2 which is a portion of the second electrode layer E2 may be provided and/or formed on the partition wall member (for example, the first partition wall member BK1). For example, the second dummy layer RML2 may be provided and/or formed on the first dummy layer RML1.

The display device according to embodiments of the disclosure may include the partition wall member disposed on the pixel defining layer and disposed in a shape surrounding the light receiving area of the light sensing pixels.

Accordingly, even though the sub-pixel and the light sensing pixel are disposed adjacent to each other due to high resolution of the display device, the light emitting layer of the sub-pixel and the light receiving layer of the light sensing pixel may be formed (or disposed) to be separated from each other by the partition wall member.

In addition, since the second sensor electrode of the light sensing pixels and the cathode electrode of the sub-pixels are formed (or disposed) to be separated from each other, a current leakage phenomenon in which a current flow from the cathode electrode to the second sensor electrode may be reduced (or eliminated). Therefore, noise may be minimized or reduced when the light sensing pixel recognizes a pattern of a user's fingerprint by sensing light reflected by an external object (for example, a user's finger or the like).

In addition, in the display device according to embodiments of the disclosure, since the partition wall member is further disposed on the pixel defining layer, an optical path is created allowing light emitted from the light emitting element of the sub-pixel to proceed to an upper portion of the display device without directly proceeding to the light receiving element of the light sensing pixel. Accordingly, accuracy in recognizing the pattern of the user's fingerprint by the light sensing pixel may be increased.

In addition, according to embodiments, even though a separate patterning process is not used, since the cathode electrode of the sub-pixel and the second sensor electrode of the light sensing pixel may be deposited to be separated from each other in a manufacturing process using a common mask by the partition wall member, a manufacturing process time may be shortened, and a process cost may be reduced.

However, an effect of the disclosure is not limited to the above-described effect, and may be variously expanded without departing from the spirit and scope of the disclosure.

While the disclosure has been particularly shown and described with reference to embodiments thereof, it will be understood by those of ordinary skill in the art that various changes in form and detail may be made therein without departing from the spirit and scope of the disclosure as defined by the following claims.

What is claimed is:

1. A display device, comprising:
a substrate; and
a plurality of unit pixels disposed on the substrate,
wherein each of the unit pixels includes a plurality of sub-pixels, a plurality of light sensing pixels, and a plurality of partition wall members,
wherein each of the sub-pixels includes a light emitting element that emits light and a light emitting area from which the light is emitted,
wherein each of the light sensing pixels includes a light receiving element that outputs a sensing signal corresponding to the light and a light receiving area that receives the light, and
wherein in a plan view, each of the partition wall members surrounds the corresponding light receiving area and overlaps at least some of the sub-pixels.

2. The display device according to claim 1, wherein one of the unit pixels comprises:
a first sub-pixel positioned in a first column of the substrate;
two (2-1)-th sub-pixels positioned in a second column adjacent to the first column in a first direction;
a third sub-pixel positioned in a third column adjacent to the second column in the first direction;
two (2-2)-th sub-pixels positioned in a fourth column adjacent to the third column in the first direction;
a first light sensing pixel positioned in the second column; and
a second light sensing pixel positioned in the fourth column.

3. The display device according to claim 2, wherein the two (2-1)-th sub-pixels and the two (2-2)-th sub-pixels emit light of a same color, and
wherein all of the color of the light emitted by the two (2-1)-th sub-pixels and the two (2-2)-th sub-pixels, a color of light emitted by the first sub-pixel, and a color of light emitted by the third sub-pixel are different.

4. The display device according to claim 2, wherein the first light sensing pixel is disposed between the two (2-1)-th sub-pixels in the second column,
wherein the second light sensing pixel is disposed between the two (2-2)-th sub-pixels in the fourth column, and
wherein the first sub-pixel, the third sub-pixel, the first light sensing pixel, and the second light sensing pixel are disposed in a same row.

5. The display device according to claim 4, wherein a partition wall member disposed in the second column among the partition wall members is spaced apart from the first light sensing pixel and overlaps the two (2-1)-th sub-pixels in at least a first partial area, and
wherein a partition wall member disposed in the fourth column among the partition wall members is spaced apart from the second light sensing pixel and overlaps the two (2-2)-th sub-pixels in at least a second partial area.

6. The display device according to claim 5, wherein, in the plan view, each of the partition wall members includes an opening area in which at least a portion is opened.

7. The display device according to claim 6, wherein the opening area included in each of the partition wall members corresponds to a direction facing the first sub-pixel and the third sub-pixel.

8. The display device according to claim 6, wherein each of the partition wall members includes a first partition wall member and a second partition wall member having a quadrangular shape of which one side is opened,
wherein the first partition wall member and the second partition wall member included in the partition wall member disposed in the second column among the partition wall members are spaced apart from each other with the first light sensing pixel interposed therebetween, and
wherein the first partition wall member and the second partition wall member included in the partition wall member disposed in the fourth column among the partition wall members are spaced apart from each other with the second light sensing pixel interposed therebetween.

9. A display device, comprising:
a substrate;
a circuit layer disposed on the substrate and including a pixel circuit and a sensor circuit;
a pixel element layer disposed on the circuit layer and including a light emitting element connected to the pixel circuit, a light receiving element connected to the sensor circuit, and a pixel defining layer disposed on the circuit layer; and
a partition wall member disposed on the pixel defining layer,
wherein the partition wall member has a reverse taper shape,
wherein a first intermediate layer integrally formed with a light emitting layer of the light emitting element and a second intermediate layer integrally formed with a light receiving layer of the light receiving element are disposed on the pixel defining layer, and
wherein the first intermediate layer and the second intermediate layer are separated from each other with respect to the partition wall member on the pixel defining layer.

10. The display device according to claim 9, wherein an angle formed between a side surface and a lower surface of the partition wall member exceeds 90°.

11. The display device according to claim 9, wherein the light emitting element includes an anode electrode, the light emitting layer is positioned on the anode electrode, and a cathode electrode is positioned on the light emitting layer, and
wherein the light receiving element includes a first sensor electrode, the light receiving layer is positioned on the first sensor electrode, and a second sensor electrode is positioned on the light receiving layer.

12. The display device according to claim 11, wherein the cathode electrode and the second sensor electrode include a same material.

13. The display device according to claim 11, wherein the cathode electrode and the second sensor electrode are separated from each other with respect to the partition wall member.

14. The display device according to claim 11, wherein the pixel defining layer is positioned on the anode electrode of the light emitting element and the first sensor electrode of the light receiving element, and includes a first opening exposing a portion of the anode electrode and a second opening exposing a portion of the first sensor electrode.

15. The display device according to claim 14, wherein the light emitting layer is disposed on the first opening and the light receiving layer is disposed on the second opening,
wherein the first intermediate layer is disposed on the pixel defining layer and is integrally formed with the light emitting layer disposed on the first opening, and
wherein the second intermediate layer is disposed on the pixel defining layer and is integrally formed with the light receiving layer disposed on the second opening.

16. The display device according to claim 15, further comprising:
a first dummy layer disposed on the partition wall member.

17. The display device according to claim 16, further comprising:
a second dummy layer disposed on the first dummy layer.

18. The display device according to claim 17, wherein the cathode electrode, the second sensor electrode, and the second dummy layer include a same material.

19. The display device according to claim 11, wherein the anode electrode and the first sensor electrode include a same material.

20. The display device according to claim 11, further comprising:
a thin film encapsulation layer positioned on the cathode electrode of the light emitting element and the second sensor electrode of the light receiving element and covering the light emitting element and the light receiving element.
